(19) United States
(12) Patent Application Publication
(10) Pub. No.: US 2025/0379140 A1
(43) Pub. Date: Dec. 11, 2025

(54) DEVICE, METHOD AND SYSTEM FOR PROVIDING (ANTI)FERROELECTRIC CAPACITORS OF VARIOUS THICKNESSES

(71) Applicant: Intel Corporation, Santa Clara, CA (US)

(72) Inventors: Yu-Ching Liao, Portland, OR (US); Nazila Haratipour, Portland, OR (US); Christopher Neumann, Portland, OR (US); Shriram Shivaraman, Portland, OR (US); Sou-Chi Chang, Portland, OR (US); Ian A. Young, Olympia, WA (US); Uygar E. Avci, Portland, OR (US)

(73) Assignee: Intel Corporation, Santa Clara, CA (US)

(21) Appl. No.: 18/736,321

(22) Filed: Jun. 6, 2024

(51) Int. Cl. H01L 23/522; H10B 51/30

(52) U.S. Cl. CPC H01L 23/5223; H10B 51/30; H10D 1/043; H10D 1/714; H10D 1/716

(57) ABSTRACT

Techniques and mechanisms for providing an (anti)ferroelectric capacitor structure. In an embodiment, an (anti)ferroelectric material layer and an electrode structure each extend vertically though a first outer electrode and a second outer electrode of a material layer stack. In a horizontal plane, the (anti)ferroelectric material layer surrounds the electrode structure. A first capacitor is formed with the first metallization layer and portions of the (anti)ferroelectric material layer and the electrode structure, wherein a second capacitor is formed with the second metallization layer and other portions of the (anti)ferroelectric material layer and the electrode structure. To facilitate improved operational characteristics, a first thickness of the first metallization layer is substantially greater than a second thickness of the second metallization layer. In another embodiment, the electrode structure tapers or otherwise decreases in horizontal width along a line of direction from the second metallization layer toward the first metallization layer.

### BACKGROUND

### 1. Technical Field

This disclosure generally relates to circuit structures and more particularly, but not exclusively, to a capacitor structure which comprises one of a ferroelectric material or an antiferroelectric material.

### 2. Background Art

Ferroelectric materials have a wide variety of applications in the modern electronic industry. These materials have been widely studied for non-volatile memory, neuromorphic applications and steep slope devices. Non-volatility, fast switching speed, scalability and reliability make these materials interesting for memory applications. Transistor scalability is one of the main key elements of increasing memory density and capacity, however scaling state-of-the-art transistors for sub 10 nm nodes presents challenges. Architectural innovation and novel materials can pave the path for moving toward future technologies.

### BRIEF DESCRIPTION OF THE DRAWINGS

The various embodiments of the present invention are illustrated by way of example, and not by way of limitation, in the figures of the accompanying drawings and in which:

FIG. 1A illustrates a cross-sectional view of an integrated circuit ferroelectric capacitor structure which extends through various metallization layers according to an embodiment.

FIG. 1B illustrates a plan view through a horizontal plane of an integrated capacitor structure according to an embodiment.

FIG. 1C illustrates an enhanced cross-sectional view of a section of an integrated capacitor structure according to an embodiment.

FIG. 1D illustrates a cross-sectional view of an integrated circuit ferroelectric capacitor structure which extends through various metallization layers according to an embodiment.

FIG. 2 illustrates a method for providing an (anti)ferroelectric capacitor structure according to an embodiment.

FIGS. 3A-3H show cross-sectional side views each illustrating a respective stage of a process to fabricate an integrated circuit capacitor structure according to an embodiment.

FIG. 4 is a cross-sectional illustration of an integrated capacitor structure, in accordance with an embodiment of the present disclosure.

FIGS. 5A-5F show cross-sectional side views each illustrating a respective stage of a process to fabricate an integrated circuit capacitor structure according to an embodiment.

FIG. 6 illustrates a system which includes a capacitor coupled to an access transistor.

FIG. 7 illustrates a computing device in accordance with embodiments of the present disclosure.

FIG. 8 illustrates an integrated circuit (IC) structure.

### DETAILED DESCRIPTION

Embodiments discussed herein variously provide techniques and mechanisms for providing an (anti)ferroelectric capacitor structure. The description herein includes numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including one or more integrated circuit capacitor structures.

In various semiconductor memory devices such as DRAMs (Dynamic Random-Access Memory), each memory cell includes one transistor and one capacitor. In DRAMs, cells require periodic reading and refreshing. Owing to the advantages of low price-per-unit-bit, and high integration, DRAMs have enjoyed widespread use in commercial applications. Dynamic random-access memory (DRAM) utilizes charge storage in capacitors as programmable bits of memory. However, with scaling feature sizes of transistors, a space available for a capacitor above each transistor may be reduced. Variability and increased leakage can also limit the possibility of further scaling access transistors. A capacitor having a columnar (e.g., cylindrical) geometry can facilitate scaling, because a footprint of the columnar capacitor may be smaller than a footprint of a transistor controlling the capacitor. However, to create a large array of programmable bits—e.g., with a 1T-1C architecture—requires a large number of singly dedicated transistors. Furthermore, since conventional cylindrical or trench capacitors are based on high-K dielectric materials as a charge-based storage device, retaining memory in a bit depends on insulating the charge from leaking to nearby interconnects and devices. Usually, a leakage path to nearby interconnects and devices is shortened with scaling.

Ferroelectric materials bridge the gap for capacitor-based memory devices, where ferroelectric materials can be used as a replacement for conventional high-K dielectric materials. Not only do ferroelectric materials have a higher dielectric constant (greater than 30) compared to high-K materials such as oxides of Hf, Zr etc, but ferroelectric materials are often split into domains having different directions of spontaneous polarization. Spontaneous polarization results from atomic separation between the constituent atoms in a ferroelectric material that create electric dipoles within the ferroelectric material. A single domain includes a large collection of dipoles having a single orientation.

Dipoles in a ferroelectric material can have their orientation altered by an externally applied electric field. When a ferroelectric material is sandwiched between two electrodes, for example as in a capacitor, applying a potential difference between the two electrodes can generate an electric field. If the electric field is sufficiently large, the direction of the spontaneous polarization can be set by the applied electric field. The applied electric field (due to the potential difference) can manipulate the direction of the polarization in the ferroelectric material. The direction of the polarization may be set in the ferroelectric material at a beginning of operation and reset at any time.

Because polarization in one or more domains in a ferroelectric material can respond to locally applied external fields, the polarization can be set (or programmed) independently over a region of the ferroelectric material covered by the one or more domains. In different material embodiments, a single domain can range between 10 nm to 50 nm. The domain sizes may also depend on a thickness of the ferroelectric material, which can vary between different materials. The number of domains, over which a polarization is to be set may depend on a spatial extent of the smallest electrode sandwiching the ferroelectric material. The direction of polarization set in the ferroelectric material corresponds to a single memory storage bit.

In accordance with some embodiments, an integrated circuit capacitor structure includes a first electrode, a ferroelectric layer around one or more exterior sides of the first electrode, and a plurality of outer electrodes. Each of the plurality of outer electrodes are electrically isolated from each other. Along at least part of its vertical extent, the first electrode tapers or otherwise generally decreases in the area (for example, the width and/or breadth) of its horizontal cross-section. Such a decreasing cross-sectional area is due, for example, to characteristics of an etching and/or other subtractive process to form a recess structure in which the ferroelectric layer and the first electrode are subsequently disposed.

In one embodiment, the plurality of outer electrodes includes a first outer electrode that is laterally adjacent to an exterior of a first portion of the ferroelectric layer, and a second outer electrode that is laterally adjacent to an exterior of a second portion of the ferroelectric layer. In one embodiment, the second outer electrode is above the first outer electrode. The polarization over a first spatial region in the ferroelectric layer between the first electrode and the first outer electrode corresponds to a first memory storage bit, and the polarization over a second spatial region in the ferroelectric layer between the first electrode and the second outer electrode corresponds to a second memory storage bit. The first electrode, the first portion of the ferroelectric layer and the first outer electrode comprise a first ferroelectric capacitor and the first electrode, the second portion of the ferroelectric layer and the second outer electrode comprise a second ferroelectric capacitor.

Because the first outer electrode and the second outer electrode are spatially isolated the direction of polarization may be independently set in the corresponding ferroelectric capacitors. When voltage is applied between a first electrode and a first outer electrode, the voltage across the first ferroelectric capacitor may not modify the second ferroelectric capacitor up to a percentage of a maximum programmable voltage. In embodiments, the voltage across a selected ferroelectric capacitor may not disturb a non-selected ferroelectric capacitor by up to 75% of the maximum programmable voltage.

Certain features of various embodiments are described herein with respect to an integrated circuit (IC) capacitor structure which provides functionality of two or more ferroelectric capacitors each with a different respective metallization layer (e.g., electrode layer). However, it is to be appreciated that such description can be extended to apply to an IC capacitor structure which additionally or alternatively provides functionality of two or more antiferroelectric capacitors, in various embodiments. As used herein, “(anti)ferroelectric”—also abbreviated as “(A)FE”—refers to the characteristic of a material or structure having either one of a ferroelectric property or an antiferroelectric property. For example, “(anti)ferroelectric capacitor structure,” or “(anti)ferroelectric capacitor” variously refer herein to a capacitor device which includes at least a layer of a ferroelectric material or a layer of an antiferroelectric material.

For example, in various embodiments a capacitor structure comprises respective portions of multiple metallization layers, as well as a first electrode and an (anti)ferroelectric layer which, in a horizontal plane, extends around the first electrode. The first electrode and the (anti)ferroelectric layer each extend vertically through the multiple metallization layers.

Along a vertical height of the first electrode, horizontal dimensions (e.g., widths) of the first electrode taper or otherwise generally decrease, and are different in each of two or more metallization layers through which the first electrode extends. In one such embodiment, the two or more metallization layers have respective vertical thicknesses which are substantially different from each other.

In providing such different vertical thicknesses of the two or more metallization layers, some embodiments variously facilitate different portions of the first electrode (the different portions each extending through a different respective one of the two or more metallization layers) each to have a respective desirable surface area. For example, some embodiments enable such different portions of the first electrode each to have substantially the same surface area. Alternatively or in addition, such embodiments enable corresponding portions of the (anti)ferroelectric layer each to have substantially the same surface area. Based on these surface areas, some embodiments enable an IC capacitor structure to provide functionality of two or more (anti)ferroelectric capacitors which have substantially the same capacitance.

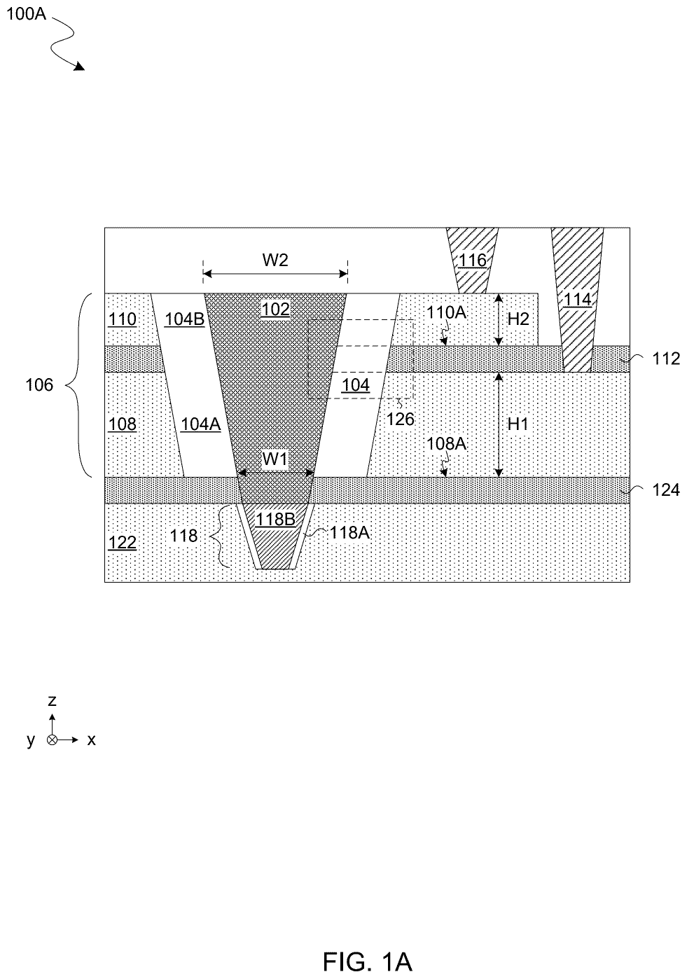

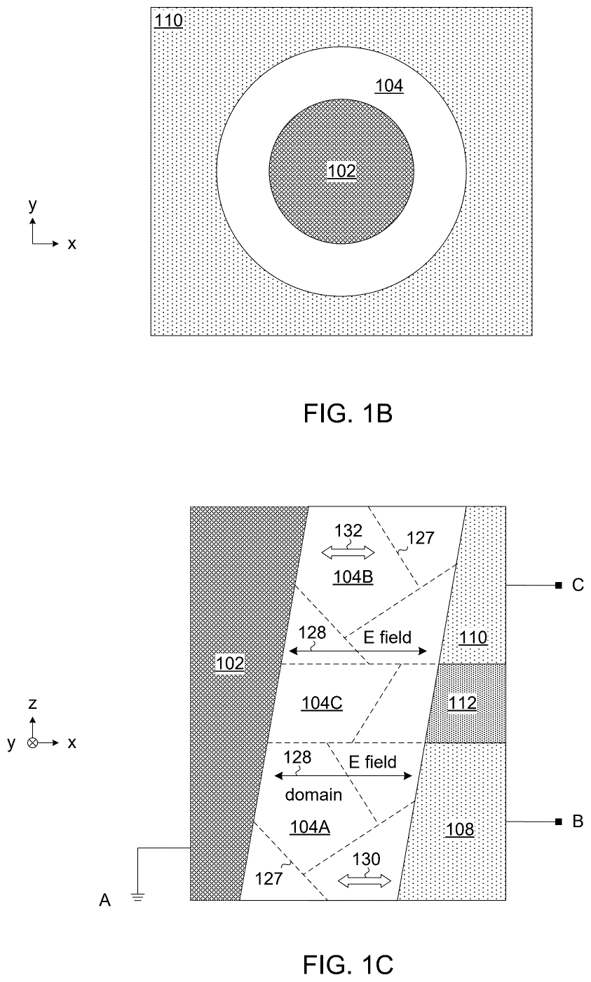

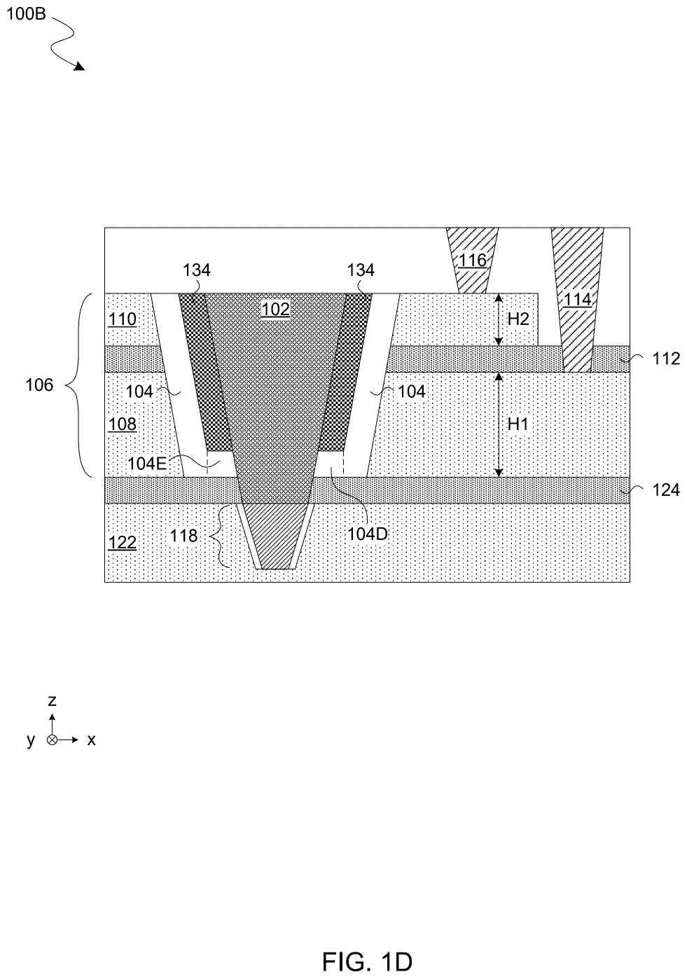

FIG. 1A illustrates a cross-sectional view of an integrated circuit (IC) capacitor structure 100A which extends through metallization layers of various thicknesses, in accordance with an embodiment. The IC capacitor structure 100A includes an electrode 102, a ferroelectric layer 104 around an exterior sidewall of the electrode 102 and a plurality of outer electrodes 106. Each of the outer electrodes in the plurality of outer electrodes 106 are electrically isolated from each other. As shown, the plurality of outer electrodes 106 includes an outer electrode 108 that is laterally adjacent to an exterior of a portion 104A of the ferroelectric layer 104 (herein ferroelectric portion 104A) and an outer electrode 110 that is laterally adjacent to an exterior of a portion 104B of the ferroelectric layer 104 (herein ferroelectric portion 104B). In one embodiment, the second outer electrode 110 is above the first outer electrode 108, as shown.

FIG. 1B is a plan view illustration of the structure in FIG. 1A, along a horizontal plane at a top side of the second outer electrode 110. In the illustrative embodiment, the electrode 102 has a circular cross section and the ferroelectric layer 104 is substantially conformal around the electrode 102.

Referring again to FIG. 1A, in an embodiment, the ferroelectric layer 104 includes a material that has a spontaneous polarization over a temperature range. A single crystal form can advantageously provide ordered domains over a vertical extent (along the z-direction) of the ferroelectric layer 104. At a Curie temperature, TC, the ferroelectric layer 104 can undergo a phase transition between an ordered and disordered states, where the dielectric constant can change by orders of magnitude. In an embodiment, the ferroelectric layer 104 has a thickness between 2 nm and 50 nm, and where in the ferro electric material includes hafnium zirconium oxide (HfZrO, also referred to as HZO, which includes hafnium, zirconium, and oxygen), silicon-doped (Si-doped) hafnium oxide (which is a material that includes hafnium, oxygen, and silicon), germanium-doped (Ge-doped) hafnium oxide (which is a material that includes hafnium, oxygen, and germanium), aluminum-doped (Al-doped) hafnium oxide (which is a material that includes hafnium, oxygen, and aluminum), yttrium-doped (Y-doped) hafnium oxide (which is a material that includes hafnium, oxygen, and (yttrium), lead zirconate titanate (which is a material that includes lead, zirconium, and titanium), barium zirconate titanate (which is a material that includes barium, zirconium and titanium), and combinations any combination of these. Some embodiments include hafnium, zirconium, barium, titanium, and/or lead, and any combinations of these materials.

Depending on the material and thickness of the ferroelectric layer 104, domains within ferroelectric layer portions 104A and 104B may be between 2 nm and 50 nm (for example). In various embodiments, some or all of the plurality of outer electrodes 106 have different respective vertical thicknesses (along the z-direction)—e.g., wherein one or more of said thicknesses depend on a vertical extent of a smallest domain in one of the ferroelectric layer portions 104A, 104B. By way of illustration and not limitation, one of said vertical thicknesses is equal to or greater than 110% of another of said vertical thicknesses. In the illustrative embodiment, the outer electrode 108 has a vertical thickness, H1 as measured from a lowermost surface 108A of the outer electrode 108. In one such embodiment, the ferroelectric layer portion 104A extends—e.g., at an oblique angle-through the vertical thickness H1 of the outer electrode 108, and along an adjoining portion of electrode 102 which also extends through the vertical thickness H1. In one example embodiment, the ferroelectric layer portion 104A that is between the electrode 102 and outer electrode 108 corresponds to a first memory storage bit.

In the illustrative embodiment, the outer electrode 110 has a vertical thickness H2, as measured from a lowermost surface 110A of the outer electrode 110. In one such embodiment, the ferroelectric layer portion 104B extends—e.g., at an oblique angle—through the vertical thickness H2 of the outer electrode 110, and along another adjoining portion of electrode 102 which also extends through the vertical thickness H2. In one such embodiment, the ferroelectric layer portion 104B that is between the electrode 102 and outer electrode 110 corresponds to a second memory storage bit.

In the illustrative embodiment, there are two outer electrodes 108 and 110, respectively. However, in other embodiments, the number of outer electrodes along an overall height of the electrode 102 may in a range of 2 to 8.

Because the outer electrode 108 and the outer electrode 110 are spatially and electrically isolated, the direction of polarization can be variously set independently in the respective ferroelectric layer portions 104A, 104B. As shown, the outer electrode 108 is vertically spaced apart from the outer electrode 110 by a vertical thickness of a dielectric 112 which is disposed therebetween. Such a vertical thickness is determined, in some embodiments, based on a coupling capacitance between electrode 108 and 110 which may impact read/write operations (RC delays). In an embodiment, the vertical thickness of dielectric 112 is at least 5 nm. In the illustrative embodiment, the dielectric 112 is directly adjacent to adjacent to the ferroelectric layer portion 104C and vertically between the outer electrode 108 and outer electrode 110.

In the illustrative embodiment, to facilitate contact with terminals, the two outer electrodes 108 and 110 have a staircase shape. As shown, the outer electrode 110 extends laterally beyond (along the x-direction) the outer electrode 108. A first contact 114 is on coupled with the outer electrode 108 and a second contact 116 is coupled with the outer electrode 110. In the illustrative embodiment, second contact is laterally between electrode 102 and the first contact 114.

The electrode 102 is further coupled with a conductive interconnect 118. In one example embodiment, conductive interconnect 118 is coupled with a transistor (not shown) and/or any of various other suitable circuit devices which (for example) facilitate operation of a memory cell which includes IC capacitor structure 100A. As shown, dielectric 122 is adjacent to the conductive interconnect 118 and a dielectric 124 is between the outer electrode 108 and dielectric 122. In the illustrative embodiment, dielectric 124 is also laterally adjacent to the electrode 102 and directly below and in contact with ferroelectric layer 104. The dielectric 124 may facilitate as an etch stop layer as well as a copper diffusion barrier layer, for example.

In embodiments, the outer electrode 108 and outer electrode 110 include titanium, tantalum, tungsten, ruthenium, or nitrides of titanium, tantalum, tungsten, ruthenium.

In embodiments, electrode 102 includes titanium, tantalum, tungsten, ruthenium, copper, or nitrides of titanium, tantalum, tungsten, ruthenium. In some embodiments, electrode 102 and the electrode 106 include a same material.

In an embodiment, the conductive interconnect 118 includes a liner layer 118A and a fill metal 118B on the liner layer 118A, as shown. In an embodiment, the liner layer 118A includes one or more of Ti, Ta, Ru or Al.

The fill metal 118B may include a material such as W or Cu.

In embodiments, dielectric layers 124 and 112 include silicon and one or more of nitrogen and carbon such as, silicon nitride, carbon doped silicon nitride or silicon carbide.

In embodiments, dielectric layer 122 includes silicon and one or more of nitrogen, oxygen and carbon such as, silicon nitride, silicon dioxide, carbon doped silicon nitride, silicon oxynitride or silicon carbide.

In embodiments contacts 114 and 116 include titanium, tantalum, tungsten, ruthenium, copper, or nitrides of titanium, tantalum, tungsten, ruthenium. In other embodiments the contacts 114 and 116 include a liner layer including ruthenium or tantalum and a fill metal such as copper or tungsten.

FIG. 1C is a cross sectional illustration of a section (inside dashed box 126) of the structure in FIG. 1A. The ferroelectric layer portion 104A may include one or more domains. As shown, ferroelectric layer portions 104A and 104B each includes a plurality of domains (separated by the dashed lines 127 in each respective portion 104A and 104B). The domains in ferroelectric layer portions 104A can respond to an external electric field 128 when a potential difference is applied between the electrode 102 (terminal A) and outer electrode 108 (terminal B) during operation. The ferroelectric layer portion 104A has an average intrinsic polarization indicated by arrow 130, that can respond to the external applied electric field 128. In the cross-sectional embodiment, the average polarization can orient in the +/−x-direction as indicated by the bidirectional arrow 130.

The domains in ferroelectric layer portions 104B can respond to an external electric field 128 when a potential difference is applied between the electrode 102 (terminal A) and outer electrode 110 (terminal C) during operation. The ferroelectric layer portion 104B has an average intrinsic polarization indicated by bidirectional arrow 132, that can respond to the external applied electric field 128. In the cross-sectional embodiment, the average polarization can orient in the +/−x-direction as indicated by the bidirectional arrow 132. The potential difference can be applied independently between electrode 110 and electrode 108, so the electrical field can be localized within ferroelectric layer portion 104A or 104B.

The applied electric field 128 does not appreciably affect an intrinsic polarization in the ferroelectric layer portion 104C, because of low levels of fringing fields within ferroelectric layer portion 104C. The thickness of the dielectric layer 112 can control the extent of fringing fields within ferroelectric layer portion 104C.

In some embodiments, the IC capacitor structure includes one or more layers between the electrode 102 and the ferroelectric layer 104.

In some traditional IC capacitor structures, a layer of an (A)FE material extends in a horizontal plane around a central electrode, and further extends vertically through multiple metallization layers which—unlike those which variously form outer electrodes 108, 110—each have substantially the same vertical thickness. In cases where the width of such a central electrode tapers or otherwise varies along the central electrode's height, various portions of such an (A)FE layer (the various portions each extending in a different respective metallization layer) have substantially different surface areas. Where a circuit device—e.g., a 1T-nC memory cell (where n is a positive integer)—comprises such a traditional IC capacitor structure, the different surface areas of the (A)FE layer portions contribute to the (A)FE capacitors having different capacitances, which in tun impacts the performance of the circuit device.

By contrast, in providing different vertical thicknesses H1, H2 (for example) of two or more metallization layers, IC capacitor structure 100A facilitates such (A)FE layer portions having intended (e.g., substantially equal) surface areas. In turn, these desirable surface areas facilitate (A)FE capacitors of IC capacitor structure 100A having intended (e.g., substantially equal) capacitances.

FIG. 1D is a cross-sectional illustration of an integrated circuit (IC) capacitor structure 100B, that includes a liner layer 134 between the electrode 102 and the ferroelectric layer 104. The liner layer 134 may be implemented to facilitate one or more processing operations as will be discussed below. In an embodiment, the liner layer 134, has a lateral thickness between 2 nm and 10 nm.

Where IC capacitor structure 100B includes liner layer 134, the ferroelectric layer 104 may have a portion that is under the liner layer 134. In the illustrative cross-sectional embodiment, the ferroelectric layer 104 has a lateral portion 104D and a lateral portion 104E under the liner layer 134.

The liner layer 134 may include a material that is the same or substantially the same as the material of the electrode 102. In other embodiments, the liner layer 134 includes a material that facilitates that offers process benefits. In some such embodiments, the liner layer 134 includes a material such as ruthenium, tungsten, titanium, tantalum, or nitrides of tungsten, titanium or tantalum.

For example, in some embodiments, a metal liner is conformally or substantially conformally deposited on the ferroelectric layer 104. In an embodiment, portions of the metal liner are etched off after deposition—e.g., by an anisotropic plasma etch process. The plasma etch process may remove portions of the metal liner which are above the conductive interconnect 118—e.g., where such portions are removed faster than portions of the metal liner which are adjacent to the interior sidewall structures of ferroelectric layer 104. After removing the metal liner from above the conductive interconnect 118, portions of the ferroelectric layer 104 and the dielectric layer 124 which are above the conductive interconnect 118 are etched to expose the conductive interconnect 118. Unetched portions of the metal liners may stay adjacent to the ferroelectric layer 104. Such a process may be utilized to protect vertically extending portions of the ferroelectric layer 104.

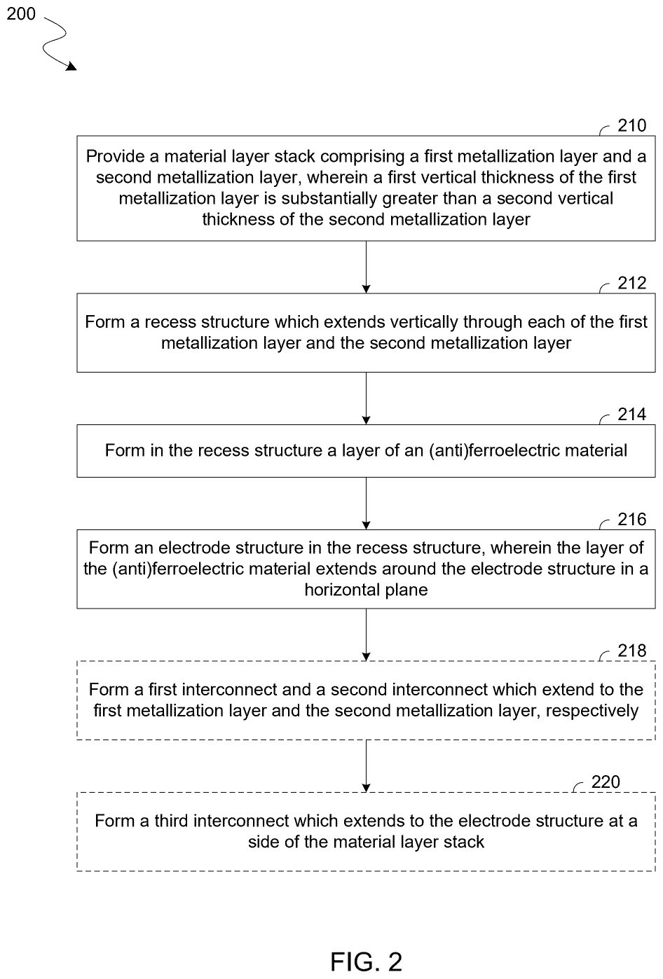

FIG. 2 shows a method 200 providing an (anti)ferroelectric capacitor structure according to an embodiment. Method 200 illustrates one example of an embodiment which fabricates (A)FE capacitors with outer electrode structures of a material layer stack, wherein two or more of the outer electrode structures have substantially different vertical thicknesses. Operations such as those of method 200 are performed to provide some or all of the functionality of IC capacitor structure 100A or IC capacitor structure 100B.

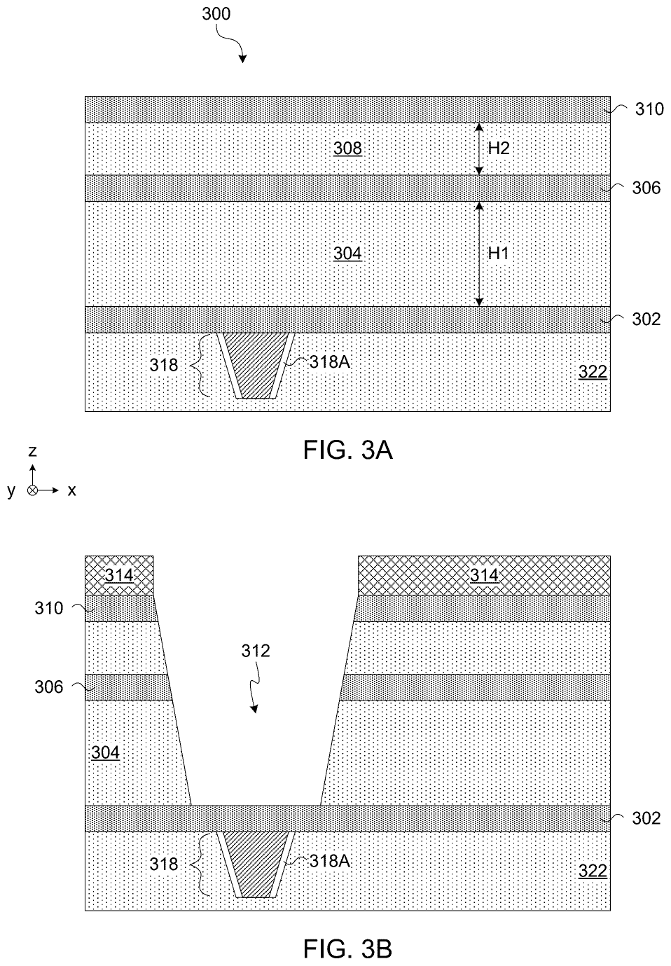

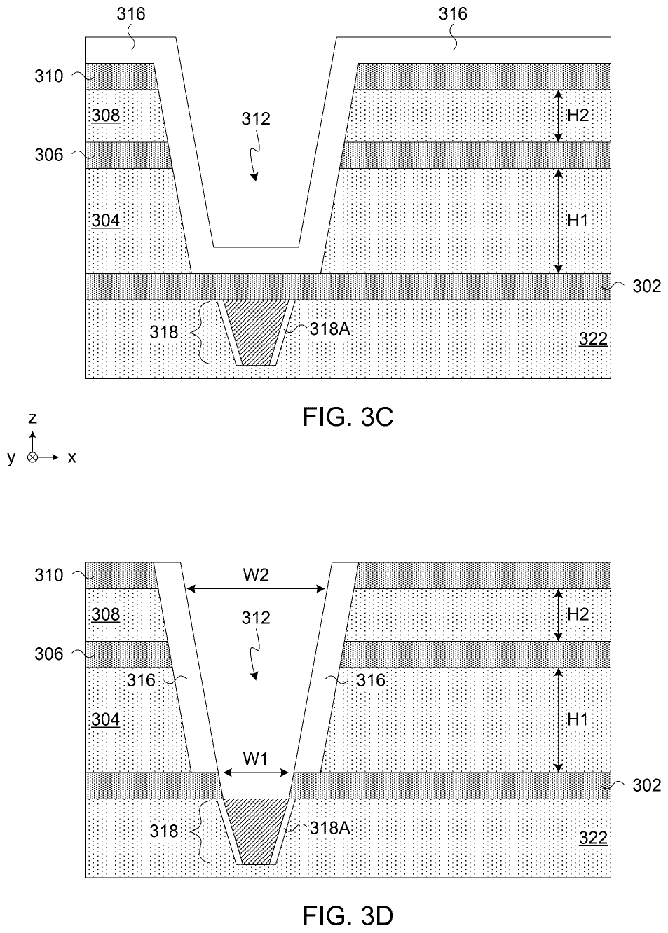

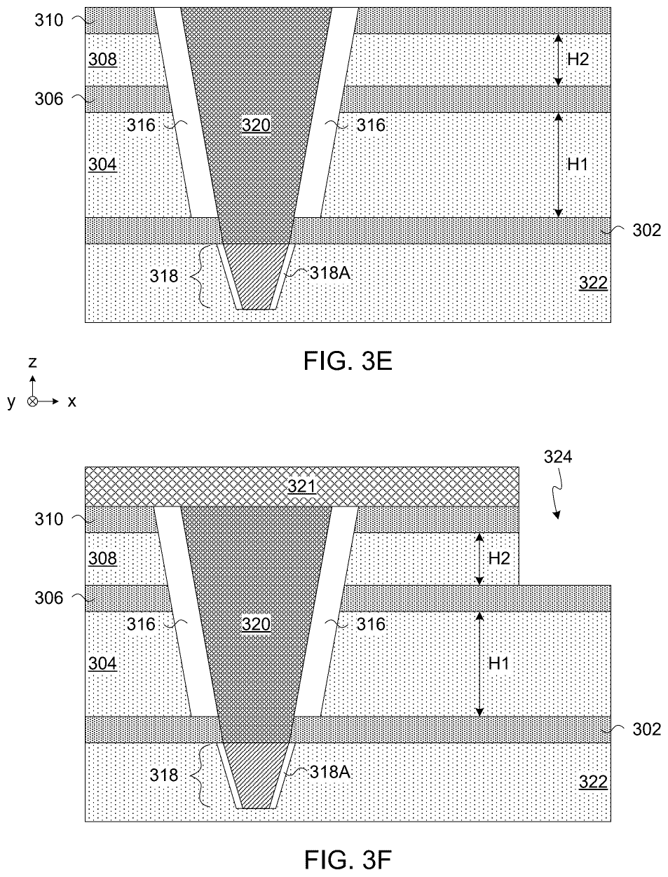

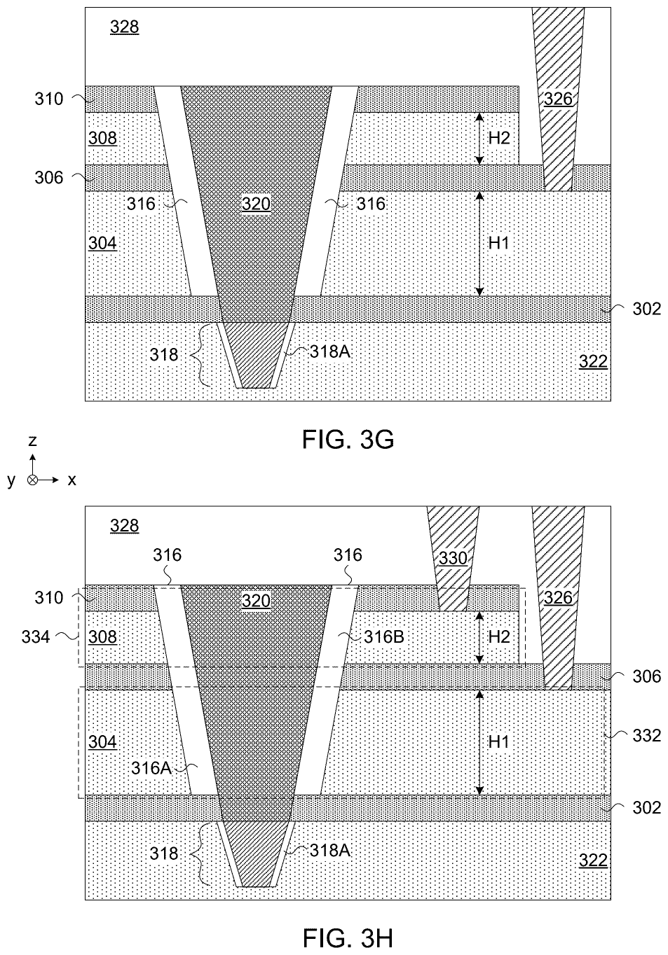

To illustrate certain features of various embodiments, method 200 is described herein with reference to structures formed by processing which is illustrated in FIGS. 3A-3H. However, method 200 is performed to form any of various additional or alternative structures, in other embodiments.

As shown in FIG. 2, method 200 comprises (at 210) providing a material layer stack comprising a first metallization layer and a second metallization layer, wherein a first vertical thickness of the first metallization layer is substantially greater than a second vertical thickness of the second metallization layer. In an example embodiment, the first metallization and the second metallization layer comprise outer electrode 108 and outer electrode 110 (respectively).

For example, FIGS. 3A-3H illustrate numerous operations to fabricate an IC capacitor structure (such one of the capacitor structures 100A, 100B), in accordance with an embodiment. FIG. 3A illustrates a material layer stack 300 formed above a conductive interconnect 318. In the illustrative embodiment, forming the material layer stack 300 includes depositing a dielectric layer 302 on the conductive interconnect 318, and on the dielectric 322. In an embodiment, the dielectric layer 302 is blanket deposited by a (PECVD) or a chemical vapor deposition (CVD) process. In an embodiment, the dielectric layer 302 includes silicon and at least one of nitrogen, or carbon, for example, silicon nitride, or silicon carbide. The dielectric layer 302 acts an etch stop during formation of a central electrode structure. A metallization layer—in this example, the illustrative metal electrode layer 304 shown—is blanket deposited on the dielectric layer 302. In an embodiment, the electrode layer 304 includes a material that is the same or substantially the same as the material of the outer electrode 108 or outer electrode 110. The electrode layer 304 may be blanket deposited using a physical vapor deposition (PVD) process, or a CVD process to a vertical thickness H1 which, for example, is between 55 nm to 300 nm. A dielectric layer 306 is blanket deposited on the electrode layer 304. In embodiments, dielectric layer 306 includes a material that is the same or substantially the same as the material of the dielectric 302. In an embodiment, dielectric layer 306 is deposited in the same manner as dielectric layer 302. The dielectric layer 306 is deposited to a thickness that is sufficient to provide electrical isolation between metal electrode layer 304 and another conductive material above. As shown, another metallization layer—i.e., metal electrode layer 308—is blanket deposited on the dielectric layer 306. In an embodiment, the electrode layer 308 includes a material that is the same or substantially the same as the material of the outer electrode 108 or outer electrode 110. The electrode layer 308 may be blanket deposited using a PVD, or a CVD process to a vertical thickness H2 which, for example, is between 50 nm to 275 nm.

The process of forming the material layer stack 300 further includes deposition of a dielectric layer 310. In an embodiment, dielectric layer 310 is blanket deposited on the electrode layer 308. In embodiments, dielectric layer 310 includes a material that is the same or substantially the same as the material of the dielectric 302. In an embodiment, dielectric layer 310 is deposited in the same manner as dielectric layer 302. The dielectric layer 310 is deposited to a thickness that is sufficient to provide a planarization stop surface, such as a thickness between 5 nm and 100 nm.

In the illustrative embodiment, the vertical thickness H1 of metal electrode layer 304 is substantially (e.g., at least 10%) greater than the vertical thickness H2 of metal electrode layer 308. In one such embodiment, the vertical thickness H1 is at least 25% greater than the vertical thickness H2—e.g., wherein the vertical thickness H1 is at least 50% greater (and in some embodiments, 100% or more) greater than the vertical thickness H2. In providing such a difference between the thicknesses H1, H2, some embodiments variously facilitate an intended relationship between—such as an equivalence of—the respective capacitances of multiple (A)FE capacitor structures.

Referring again to FIG. 2, method 200 further comprises (at 212) forming a recess structure which extends vertically through each of the first metallization layer and the second metallization layer. In an embodiment, etch and/or other subtractive processing results in the recess structure tapering or otherwise generally decreasing in horizontal width along the vertical height of the recess structure.

In some embodiments, the material layer stack further comprises a first dielectric layer and a second dielectric layer on opposite respective sides of the second metallization layer, wherein the first dielectric layer is between the first metallization layer and the second metallization layer. In one such embodiment, formation of the recess structure at 212 comprises forming an undercut structure with the second metallization layer, the first dielectric layer and the second dielectric layer.

For example, FIG. 3B is a cross-sectional illustration of the structure of FIG. 3A following the formation of a recess structure 312 in the material layer stack 300. In an embodiment, a mask 314 is formed on the dielectric layer 310. The mask 314 defines locations for a central electrode to be formed. In an embodiment, a plasma etch process is utilized to sequentially etch the dielectric layer 310, the metal electrode layer 308, the dielectric layer 306 and the metal electrode layer 304. In various embodiments, the plasma etch is halted after exposure of the dielectric layer 302 so that the conductive interconnect 318 is not exposed. In another embodiment, the same etching is continued to remove a portion of dielectric layer 302 to expose conductive interconnect 318 (and, in some embodiments, a liner layer 318A). The mask 314 may be removed after the etch process.

In the illustrative embodiment, recess structure 312 is that of a tapered recess structure which formed by some or all of dielectric layers 302, 306, 310 and metal electrode layers 304, 308. In the x-z plane plane of the cross-sectional view shown, sides of the tapered recess structure variously extend each at a respective oblique angle from a top of dielectric layer 302 to a top of metal electrode layer 308.

Referring again to FIG. 2, method 200 further comprises (at 214) forming in the recess structure a layer of an (anti)ferroelectric material. For example, FIG. 3C is a cross-sectional illustration of the structure of FIG. 3B following the formation of a ferroelectric layer 316 in the recess structure 312. In an embodiment, the ferroelectric layer 316 is blanket deposited on a top surface of the dielectric layer 302, on the obliquely angled sidewalls of the dielectric layer 310, the electrode layer 308, the dielectric layer 306, and the electrode layer 304, as well as on a top surface of dielectric layer 310. In an embodiment, the ferroelectric layer 316 includes a material that is the same or substantially the same as the material of the ferroelectric layer 104. The ferroelectric layer 316 is deposited to a thickness of 2 nm to 20 nm, for example. In an embodiment, a physical vapor deposition process is utilized to blanket deposit ferroelectric layer 316. In some embodiments, an atomic layer deposition (ALD) process may be utilized to deposit the ferroelectric layer 316. In some embodiments, a portion of ferroelectric layer 316 extends to cover that portion of dielectric layer 302 which covers conductive interconnect 318—e.g., wherein said portion of ferroelectric layer 316 is subsequently etched or otherwise removed to expose said portion of dielectric layer 302.

In various embodiments, a high temperature anneal is performed to crystallize the ferroelectric layer 316. For example, a substrate (not shown) housing the structure in FIG. 3C is heated. In one such embodiment, ferroelectric layer 316 includes a material that is in single or poly crystalline form and has a spontaneous polarization that are directed in various directions. There may not be a net polarization in the ferroelectric layer 316. Polarization can vary across different domains in the ferroelectric layer 316. As the substrate is heated, at a temperature corresponding to a Curie temperature, T_{C}, ferroelectric layer 316 can undergo a phase transition between an ordered and disordered states, where the dielectric constant can change by orders of magnitude. The substrate can then be cooled. In an embodiment, an external electric field may be applied to set a uniform direction of polarization during the cooling process. The ferroelectric layer 316 is poled, where a remnant polarization is set. As shown, a lateral width of the recess structure 312 is reduced after formation of the ferroelectric layer 316.

FIG. 3D is a cross-sectional illustration of the structure of FIG. 3C following the process to etch and remove portions of the ferroelectric layer 316 from above the dielectric layer 310 and from a portion of dielectric layer 302 which is over conductive interconnect 318. In an embodiment, a plasma etch process may be utilized. The ferroelectric layer 316 is subsequently etched from in the opening above the dielectric layer 302 and from above the dielectric layer 310. In some embodiments, the dielectric layer 302 functions as an etch stop layer during etching of the ferroelectric layer 316. An etch stop layer can be important if the material of the conductive interconnect 318 includes copper.

A plasma etch process that is selective to the dielectric layer 302 may be utilized to etch the dielectric layer 302 that is exposed after etching the ferroelectric layer 316 in the recess structure 312. An entire upper surface of the conductive interconnect 318 may be exposed after etching of the dielectric layer 302. Whether an entire upper surface or a portion of the conductive interconnect 318 is exposed may depend on a horizontal width W1 of the recess structure 312 at dielectric layer 302 (e.g., wherein the horizontal width W1 is substantially less than a horizontal width W2 of recess structure 312 at a top of metal electrode layer 308.

Referring again to FIG. 2, method 200 further comprises (at 216) forming an electrode structure in the recess structure, wherein the layer of the (anti)ferroelectric material extends around the electrode structure in a horizontal plane. In an embodiment, forming the electrode structure at 216 comprises forming both a first electrode portion which extends through the first metallization layer, and a second electrode portion which extends through the second metallization layer. Furthermore, forming the (anti)ferroelectric material layer at 214 comprises forming both a first ferroelectric portion which extends through the first metallization layer, and a second ferroelectric portion which extends through the second metallization layer.

In one such embodiment, a first horizontal width of the first electrode portion is substantially less than a second horizontal width of the second electrode portion. For example, in a vertical cross-section, the electrode structure tapers in horizontal width along a line of direction from the second metallization layer toward the first metallization layer. Alternatively or in addition, in such a vertical cross-section, the electrode structure forms a substantial, and step-wise, change in horizontal width.

In various embodiments, a first capacitor is formed with the first metallization layer, the first electrode portion and the first ferroelectric portion—e.g., wherein a second capacitor is formed with the second metallization layer, the second electrode portion and the second ferroelectric portion. In some embodiments, the second metallization layer is between the first metallization layer and a third metallization layer of the material layer stack, wherein the second vertical thickness of the second metallization layer is substantially greater than a third vertical thickness of the third metallization layer. Furthermore, the electrode structure further comprises a third electrode portion which extends through the third metallization layer, wherein the layer of the (anti)ferroelectric material comprises a third ferroelectric portion which extends through the third metallization layer. In one such embodiment, a third capacitor is formed with the third metallization layer, the third electrode portion and the third ferroelectric portion.

For example, FIG. 3E is a cross-sectional illustration of the structure of FIG. 3D following the formation of a central electrode structure 320. In an embodiment, an electrode layer is deposited into the recess structure 312 onto a top surface of the conductive interconnect 318, and in a region between the obliquely angled interior side structures of ferroelectric layer 316. In an embodiment, the electrode layer includes a material that is the same or substantially the same as the material of the electrode 102 described above. A planarization process may be performed, for example, to remove the electrode layer from above the dielectric layer 310. In an embodiment, the planarization process includes a chemical mechanical planarization (CMP) process. The process of planarization forms an electrode 320. In some embodiments, multiple successive deposition processes are performed to form electrode 320—e.g., wherein a liner layer of a first metal is first formed along ferroelectric layer 316, and a central electrode of a second metal then formed in the liner layer.

Referring again to FIG. 2, method 200 may further comprise one or more operations to facilitate coupling of the IC capacitor structure to one or more other circuit devices, although some embodiments are not limited in this regard. By way of illustration and not limitation, method 200 further comprises (at 218) forming a first interconnect and a second interconnect which extend to the first metallization layer and the second metallization layer, respectively. Additionally or alternatively, method 200 further comprises (at 220) forming a third interconnect—e.g., conductive interconnect 118—which extends to the electrode structure at a side of the material layer stack. In one such embodiment, the one or more operations couple the IC capacitor structure to a transistor, wherein a memory cell comprises the transistor and (A)FE capacitors of the IC capacitor structure.

For example, FIG. 3F is a cross-sectional illustration of the structure of FIG. 3E following the formation of a mask 321 on the electrode 320, on upper portions of ferroelectric layer 316 and on the dielectric layer 310. The mask 321 defines a location for forming a contact to couple with the electrode layer 304. In an embodiment, a plasma etch that is similar to the plasma etch is utilized to form the recess structure 312, described above, is utilized. Recess structure 324 is further formed by etching portions of each of the dielectric layer 310 and the electrode layer 308.

FIG. 3G is a cross-sectional illustration of the structure of FIG. 3F following the formation of a contact structure 326. In an embodiment, a dielectric 328 is formed in the recess structure 324 and on the dielectric layer 310, on top surface of the electrode 320, and on top portions of the ferroelectric layer 316. In an embodiment, an opening is formed in the dielectric 328 and contact electrode material is deposited in the opening and on an uppermost surface of the dielectric 328. In an embodiment, the contact electrode material includes a material that is the same or substantially the same as the material of the conductive interconnect 318. After the contact electrode material is deposited, a planarization process may be carried out to form the contact structure 326 by removing any excess contact electrode material from the uppermost surface of the dielectric 328.

FIG. 3H illustrates the structure of FIG. 3G following the formation of a contact structure 330 on the electrode layer 308. In an embodiment, contact 330 is formed by etching an opening in the dielectric 328 and in the dielectric layer 310. In an embodiment, a contact electrode material is deposited in the opening and on an uppermost surface of the dielectric 328. In an embodiment, the contact electrode material includes a material that is the same or substantially the same as the material of contact structure 326. After the contact electrode material is deposited, a planarization process may be carried out to form the contact structure 330 by removing any excess contact electrode material from the uppermost surface of the dielectric 328.

Formation of the contact structures 326 and 330 enables two independently programmable ferroelectric (FE) capacitors 332 and 334 as indicated by the dashed boxes. As shown, FE capacitor 332 includes a lower portion of electrode 320, a lower portion 316A of ferroelectric layer portion 316 and electrode 304. By contrast, FE capacitor 334 includes a top portion of electrode 320, an upper portion 316B of ferroelectric layer 316, and electrode 308. The electrode 320 and conductive interconnect 318 are shared by capacitors 332 and 334.

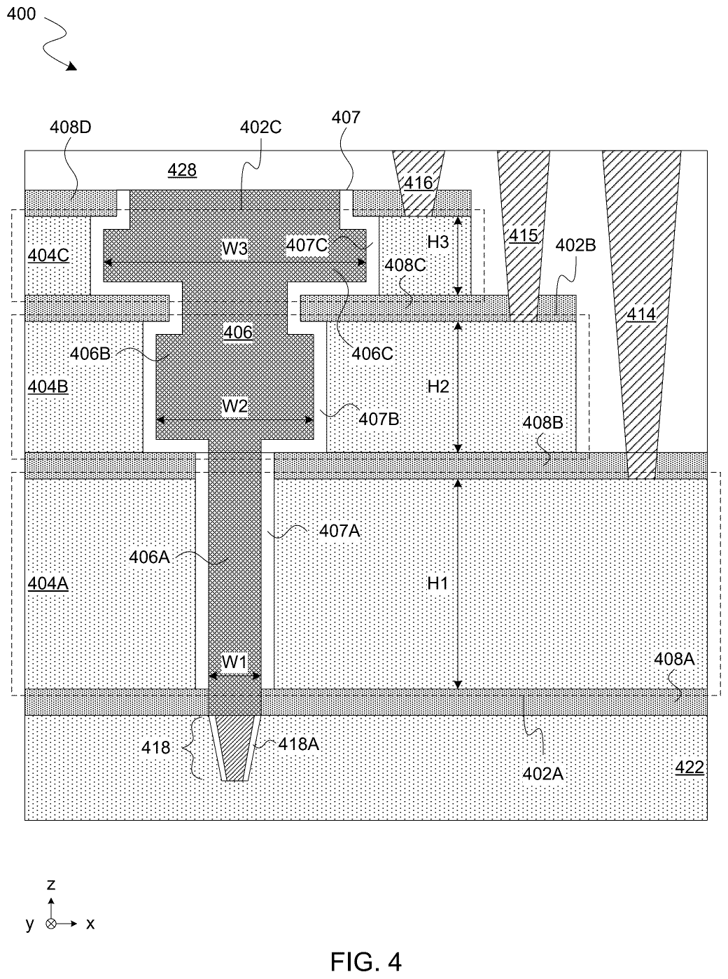

FIG. 4 is a cross-sectional illustration of an integrated circuit (IC) capacitor structure 400, in accordance with an embodiment. The IC capacitor structure 400 includes a vertically stacked arrangement of multiple electrodes-such as the illustrative electrodes 404A, 404B, 404C shown-which are each formed by a different respective metallization layer. The vertically stacked arrangement is formed on a dielectric 422 which (for example) has formed therein a conductive interconnect 418 comprising a liner layer 418A and a fill metal 418B on the liner layer 418A. In embodiments, a given one of electrodes 404A, 404B, 404C comprises any of various suitable conductive metals which (for example) include titanium, tantalum, tungsten, ruthenium, or nitrides of titanium, tantalum, tungsten, ruthenium.

In an embodiment, a dielectric layer 408A is disposed between dielectric 422 and electrode 404A—e.g., wherein another dielectric layer 408B is disposed between, and provides at least partial insulation between, electrodes 404A, 404B. In one such embodiment, another dielectric layer 408C is disposed between, and provides at least partial insulation between, electrodes 404B, 404C—e.g., wherein an additional dielectric layer 408D is formed on electrode 404C. In an illustrative embodiment, one or more of dielectric layers 408A, 408B, 408C, 408D each has a respective vertical thickness which (for example) is at least 5 nm. In embodiments, a given one of dielectric layers 408A, 408B, 408C comprises any of various suitable electrical insulator materials which (for example) include silicon and one or more of nitrogen and carbon such as, silicon nitride, carbon doped silicon nitride or silicon carbide.

The IC capacitor structure 400 further includes an electrode 406 which extends in a vertical (z-axis) direction through the electrodes 404A, 404B, 404C and through dielectric layers 408A, 408B, 408C, 408D. For example, electrode 406 comprises electrode portions 406A, 406B, 406C which variously extend vertically through electrodes 404A, 404B, 404C (respectively).

In an embodiment, a ferroelectric layer 407 of IC capacitor structure 400 surrounds electrode 406 in one or more horizontal (x-y) planes. The ferroelectric layer 407 comprises ferroelectric portions 407A, 407B, 407C which variously extend horizontally around electrode portions 406A, 406B, 406C (respectively) and vertically through electrodes 404A, 404B, 404C (respectively).

In one such embodiment, a FE capacitor 402A of IC capacitor structure 400 comprises electrode portion 406A, ferroelectric portion 407A and at least a portion of electrode 404A. Furthermore, another FE capacitor 402B of IC capacitor structure 400 comprises electrode portion 406B, ferroelectric portion 407B and at least a portion of electrode 404B. Further still, another FE capacitor 402C of IC capacitor structure 400 comprises electrode portion 406C, ferroelectric portion 407C and at least a portion of electrode 404C.

In one such embodiment, a dielectric 428 is disposed on a top surface of dielectric layer 408D—e.g., wherein the dielectric 428 extends into a recess portion to exposed surfaces of dielectric layer 408C and dielectric layer 408B. Contact structures 414, 415, 416 of IC capacitor structure 400 variously extend through dielectric 428 to electrodes 404A, 404B, 404C (respectively). In an embodiment, FE capacitors 402A, 402B, 402C are able to be variously charged or discharged—e.g., each independently via conductive interconnect 418 and a respective one of contact structures 414, 415, 416.

As an artefact of a subtractive processing (e.g., comprising one or more patterned etches) of the metallization layers and the dielectric layers 408A, 408B, 408C, electrode 406 exhibits various horizontal widths each at a different respective level along the height of electrode 406. By way of illustration and not limitation, electrode 406A has a local maximum width W1 which is substantially smaller than a local maximum width W2 of electrode 406B (which, in turn, is substantially smaller than a local maximum width W3 of electrode 406C).

Although some embodiments are not limited in this regard, electrode 406 (and, for example, ferroelectric layer 407) forms at least in part one or more undercut structures each between a respective two of dielectric layers 408A, 408B, 408C, 408D. By way of illustration and not limitation, a first undercut structure is formed at least in part with the local maximum horizontal width W2—e.g., wherein the width W2 is greater than a horizontal width of electrode 406 at dielectric layer 408B and/or is greater than another horizontal width of electrode 406 at dielectric layer 408C. Alternatively or in addition, a second undercut structure is formed at least in part with the local maximum horizontal width W3—e.g., wherein the width W3 is greater than a horizontal width of electrode 406 at dielectric layer 408C and/or is greater than another horizontal width of electrode 406 at dielectric layer 408D.

In various embodiments, two or more metallization layers of IC capacitor structure 400 have different respective vertical thicknesses (along the z-direction)—e.g., wherein a vertical thickness H1 of electrode 404A is substantially greater than a vertical thickness H2 of electrode 404B, which in turn, is substantially greater than a vertical thickness H3 of electrode 404C. In the illustrative embodiment, the vertical thickness H1 of electrode 404A is substantially greater than the vertical thickness H2 of electrode 404B (that is, greater by at least 10% of the vertical thickness H2). In one such embodiment, the vertical thickness H2 of electrode 404B is substantially greater than the vertical thickness H3 of electrode 404C (that is, greater by at least 10% of the vertical thickness H3).

In providing, different respective vertical thicknesses H1, H2, H3 of electrodes 404A, 404B, 404C—e.g., to compensate at least in part for different respective widths of electrode portions 406A, 406B, 406C-some embodiments variously eliminate or otherwise mitigate differences between the respective surface areas of ferroelectric portions 407A, 407B, 407C. As a result, such embodiments variously prevent or otherwise mitigate differences between the respective capacitances of the FE capacitors 402A, 402B, 402C.

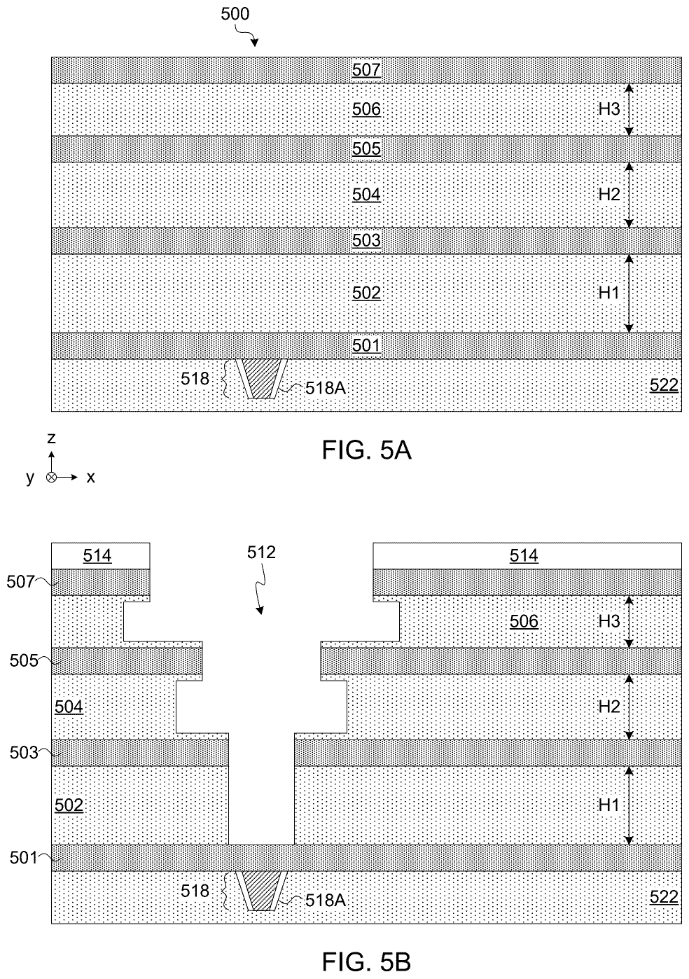

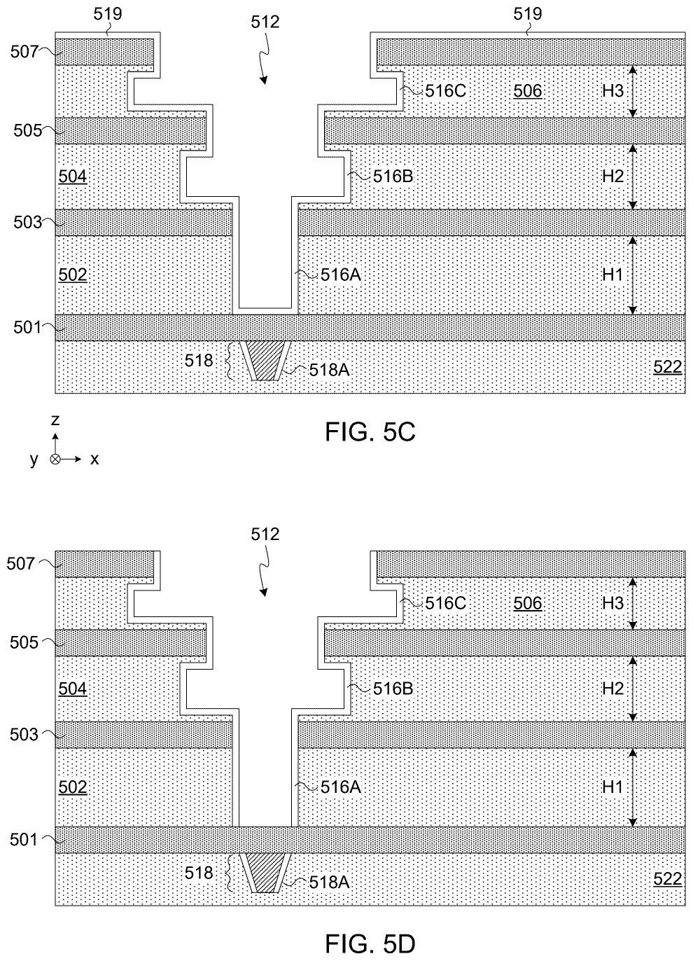

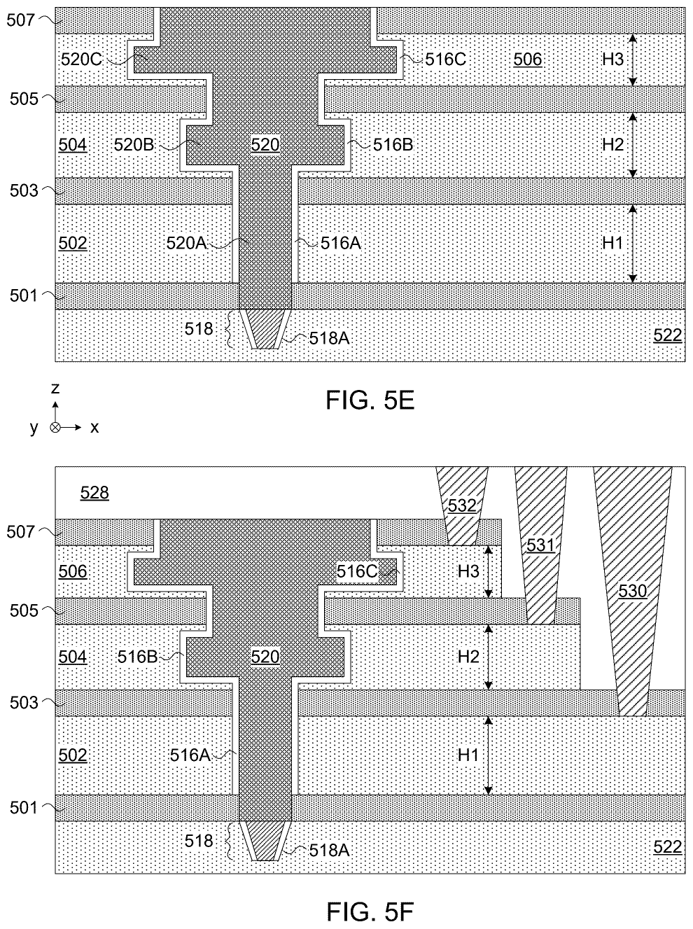

FIGS. 5A-5F illustrate numerous operations to fabricate an IC capacitor structure, in accordance with an embodiment. FIG. 5A illustrates a material layer stack 500 on a dielectric 522 which (for example) has formed therein a conductive interconnect 518 which includes a liner layer 518A and a fill metal on the liner layer 518A.

In the illustrative embodiment, forming the material layer stack 500 includes successively deposing alternating dielectric layers and metallization layers on the dielectric 522. In the example embodiment shown, such layers include an interleaved arrangement of dielectric layers 501, 503, 505, 507 and electrode layers 502, 504, 506. One or more of dielectric layers 501, 503, 505, 507 each comprise a material that (for example) is the same or substantially the same as the material of one of dielectric 112 or dielectric 124. For example, one or more of dielectric layers 501, 503, 505, 507 is formed by a process that is the same or substantially the same as the process utilized to deposit one of dielectrics 112, 124. In an embodiment, a given one of dielectric layers 501, 503, 505, 507 includes any of various suitable dielectric materials which, for example, comprise silicon and oxygen (and, in some embodiments, one of carbon or nitrogen). By way of illustration and not limitation, a given one of dielectric layers 501, 503, 505, 507 comprises any of various suitable combinations of silicon and oxygen with carbon doping, or of silicon, oxygen and nitrogen, or of silicon, oxygen, nitrogen and carbon, or of silicon and oxygen.

Alternatively or in addition, one or more of electrode layers 502, 504, 506 each comprise a material that is the same or substantially the same as the material of outer electrode 108 or outer electrode 110. For example, one or more of electrode layers 502, 504, 506 is formed by a process that is the same or substantially the same as the process utilized to deposit a conductor of one of outer electrodes 108, 110. In one such embodiment, a given one of electrode layers 502, 504, 506 may be blanket deposited using a PVD, or a CVD process—e.g., to a thickness between 50 nm and 300 nm.

In various embodiments, some or all of the metallization layers of material layer stack 500 have different respective vertical thicknesses (along the z-direction)—e.g., wherein a vertical thickness H1 of electrode layer 502 is substantially greater than a vertical thickness H2 of electrode layer 504, which in turn, is substantially greater than a vertical thickness H3 of electrode layer 506. In the illustrative embodiment, the vertical thickness H1 of electrode layer 502 is greater than the vertical thickness H2 of electrode layer 504 by at least 10% of that vertical thickness H2—for example, by at least 25% and, in some embodiments, by at least 50% (e.g., by at least 100%). In one such embodiment, the vertical thickness H2 of electrode layer 504 is greater than the vertical thickness H3 of electrode layer 506 by at least 10% of that vertical thickness H3—for example, by at least 25% and, in some embodiments, by at least 50% (e.g., by at least 100%)

In providing such differences between the thicknesses H1, H2, H3, some embodiments variously prevent or otherwise mitigate one or more capacitance variances which would otherwise arise due at least in part to width variation in a recess structure which is subsequently formed in material layer stack 500A.

FIG. 5B is a cross-sectional illustration of the structure of FIG. 5A following the formation of a recess structure 512 in the material layer stack 500. In an embodiment, a mask 514 is formed on the dielectric layer 505. The mask 514 defines locations for a central electrode to be formed. In an embodiment, a plasma etch process, wet chemical etch, or a combination thereof is utilized to sequentially etch the dielectric layer 507, the metal electrode layer 506, the dielectric layer 505, the metal electrode layer 504, the dielectric layer 503 and the metal electrode layer 502. In some embodiments, the plasma etch is halted after exposure of the dielectric layer 501 so that the conductive interconnect 518 is not exposed. The mask 514 may be removed after the etch process.

In various embodiments, one or more etch processes—e.g., some or all of which are performed through mask 514—contribute to horizontal cross-sections of recess structure 512 becoming successively smaller in width (and, for example, in area) along a vertical line of direction from dielectric layer 507 toward dielectric layer 501. In the example embodiment shown, such horizontal cross-sections exhibit step-wise changes in width—e.g., including step-wise changes each at a respective one of dielectric layers 501, 503, 505, 507.

In an alternative embodiment, recess structure 512 has a substantially tapered shape such as that of recess structure 312.

Although some embodiments are not limited in this regard, etching of material layer stack 500 through mask 514 contributes to recess structure 512 forming one or more undercut structures each between a respective two of dielectric layers 501, 503, 505, 507. In one such embodiment, a first undercut structure of recess structure 512 is formed by a first local maximum horizontal width at a region between dielectric layer 505 and dielectric layer 507—e.g., wherein the first local maximum width is greater than a horizontal width of recess structure 512 at dielectric layer 505 and/or is greater than another horizontal width of recess structure 512 at dielectric layer 507. Alternatively or in addition, a second undercut structure of recess structure 512 is formed by a second local maximum horizontal width at a region between dielectric layer 503 and dielectric layer 505—e.g., wherein the second local maximum width is greater than a horizontal width of recess structure 512 at dielectric layer 503 and/or is greater than another horizontal width of recess structure 512 at dielectric layer 505.

FIG. 5C is a cross-sectional illustration of the structure of FIG. 5B following the formation of a ferroelectric layer 519 in the recess structure 512. In an embodiment, the ferroelectric layer 519 is blanket deposited on a top surface of the dielectric layer 501, on respective interior side structures of the dielectric layers 503, 505, and 507, on respective interior side structures of the electrode layers 502, 504, 506, and on a top surface of dielectric layer 507. In an embodiment, the ferroelectric layer 519 includes a material that is the same or substantially the same as the material of one of ferroelectric layers 104, 316. The ferroelectric layer 519 is deposited to a thickness of 2 nm to 20 nm, in some embodiments. In an embodiment, a physical vapor deposition process is utilized to blanket deposit ferroelectric layer 519. In an embodiment, an atomic layer deposition (ALD) process may be utilized to deposit the ferroelectric layer 519. An ALD process may conformally deposit the ferroelectric layer 519 on some or all sides of recess structure 512.

FIG. 5D is a cross-sectional illustration of the structure of FIG. 5C following the process to etch portions of the ferroelectric layer 519. In an embodiment, a sacrificial fill material is deposited in the recess structure 512 and is selectively etched to expose a portion of ferroelectric layer 519 which is on dielectric layer 507. In an embodiment, after an etch process, the sacrificial fill material is partially removed from the recess structure 512 but remains in the undercut structures thereof. In an embodiment, a plasma etch process is utilized to etch the ferroelectric layer 519 from above the dielectric layer 501. After such etching of the ferroelectric layer 519, the dielectric layer 501 is exposed and etched. The conductive interconnect 518 is exposed after a process to etch the dielectric layer 501. In other embodiments, a wet etch process may be utilized to etch dielectric layer 501. After exposing the conductive interconnect 518 the sacrificial material may be removed from recess structure 512.

In other embodiments, not shown, a metal liner may be conformally or substantially conformally deposited on the ferroelectric layer 519. In an embodiment, portions of the metal liner may be etched off after deposition by an anisotropic plasma etch process. The plasma etch process may remove portions of the metal liner above the conductive interconnect 518 faster than portions of the metal liner adjacent to ferroelectric layer 519 that is on interior side structures of recess structure 512. After removing the metal liner from above the conductive interconnect 518, the ferroelectric layer 519 and dielectric layer 501 above the conductive interconnect 518 may be etched to expose the conductive interconnect 518. Unetched portions of the metal liners may stay adjacent to the ferroelectric layer 519. Such a process may be utilized to protect other portions of the ferroelectric layer 519 which are at or above electrode layer 502.

FIG. 5E is a cross-sectional illustration of the structure of FIG. 5D following the formation of electrode 520 in the recess structure 512. In an embodiment, an electrode material is deposited into the opening of recess structure 512 and onto exposed portions of ferroelectric layer 519 and conductive interconnect 518. The electrode material fills one or more undercut structures of recess structure 512, in some embodiments. In an embodiment, a planarization process is performed to remove excess electrode material from above the surface of dielectric layer 507.

In an embodiment, a CMP process may be utilized to planarize and remove excess electrode material from above the dielectric layer 507. The planarization process forms an electrode structure 520 which changes in horizontal width—e.g., in a step-wise manner-along its vertical height. By way of illustration and not limitation, a local maximum horizontal width of electrode 520 between dielectric layers 505, 507 is substantially greater than another local maximum horizontal width of electrode 520 between dielectric layers 503, 505 (which, in turn, is substantially greater than another horizontal width of electrode 520 between dielectric layers 501, 503).

In an embodiment, remaining portions of ferroelectric layer 519 variously surround corresponding portions of electrode 520 each in a respective horizontal (x-y) plane. By way of illustration and not limitation, a remaining ferroelectric portion 516A of ferroelectric layer 519 surrounds an electrode portion 520A which is between dielectric layers 501, 503. Alternatively or in addition, a remaining ferroelectric portion 516B of ferroelectric layer 519 surrounds an electrode portion 520B which is between dielectric layers 503, 505. Alternatively or in addition, a remaining ferroelectric portion 516C of ferroelectric layer 519 surrounds an electrode portion 520C which is between dielectric layers 505, 507.

In one such embodiment, a first FE capacitor comprises electrode portion 520A, ferroelectric portion 516A and at least a portion of electrode layer 502—e.g., wherein a second FE capacitor comprises electrode portion 520B, ferroelectric portion 516B and at least a portion of electrode layer 504, and wherein a third FE capacitor comprises electrode portion 520C, ferroelectric portion 516C and at least a portion of electrode layer 506.

In providing, different respective vertical thicknesses of electrode layers 502, 502, 506—e.g., to compensate at least in part for different respective widths of electrode portions 520A, 520B, 520C-some embodiments variously prevent or otherwise mitigate differences between the respective surface areas of ferroelectric portions 516A, 516B, 516C. As a result, such embodiments variously prevent or otherwise mitigate differences between the respective capacitances of the first, second, and third FE capacitors.

FIG. 5F is a cross-sectional illustration of the structure of FIG. 5E following the formation of contacts 530, 531, 530. In an embodiment, a masked etch and/or other suitable pattering process is performed to expose respective portions of dielectric layers 503, 505, 507. A dielectric 528 is then deposited on exposed portions of dielectric layers 503, 505, 507, on a top surface of the electrode 520, and on the top portion 516C of the ferroelectric layer. Additional patterned etching is then performed to selectively expose respective surfaces of electrode layers 502, 504, 506—e.g., through dielectric layers 503, 505, 507 (respectively).

In one such embodiment, a contact electrode material is deposited through patterned structures of dielectric 528 (and, for example, through patterned structures of dielectric layers 503, 505, 507) onto exposed surfaces of electrode layers 502, 504, 506. In an embodiment, the contact electrode material includes a material that is the same or substantially the same as the material of the conductive interconnect 518. After the contact electrode material is deposited, a planarization process may be carried out to form the contact structures 530, 531, 532 by removing any excess contact electrode material from the uppermost surface of the dielectric 528.

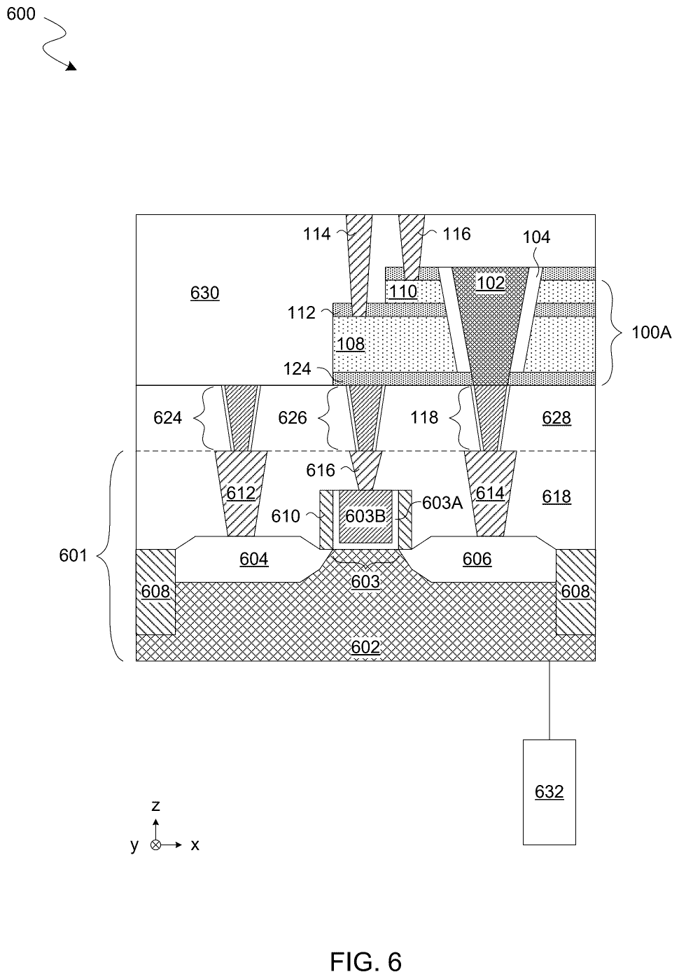

FIG. 6 illustrates a system 600 which includes an IC capacitor structure—such as one of IC capacitor structures 100A, 100B, 400—coupled to an access transistor 601. Although an IC capacitor structure 100A is shown as being located over access transistor 601, some embodiments are not limited with respect to a particular orientation and/or other positioning of a capacitor structure relative to a corresponding access transistor.

Referring again to FIG. 6, in an embodiment, the transistor 601 is on a substrate 602 and has a gate 603, a source region 604, and a drain region 606. In the illustrative embodiment, an isolation 608 is adjacent to the source region 604, drain region 606 and portions of the substrate 602. In some embodiments, such as is shown, a pair of sidewall spacers 610 are on opposing sides of the gate 603. Although the illustrative transistor 601 is represented as a planar transistor, any of various alternative types of transistors are instead coupled to facilitate access to IC capacitor structure 100A, in different embodiments.

The transistor 601 further includes a source contact 612 above and electrically coupled to the source region 604, a drain contact 614 above and electrically coupled to the drain region 606, and a gate contact 616 above and electrically coupled to the gate 603, as illustrated. The transistor 601 also includes dielectric 618 adjacent to the gate 603, source region 604, drain region 606, isolation 608, sidewall spacers 610, source contact 612, drain contact 614 and gate contact 616.

The gate contact 616 and source contact 612 are each coupled with interconnects. In the illustrative embodiment, gate contact 616 is coupled with a gate interconnect 626 and the source contact 612 is coupled with a source interconnect 624. A dielectric 628 is adjacent to source interconnect 626 and gate interconnect 624. In an embodiment, the system 600 further includes a battery and antenna inside a unit 632 which is coupled to the transistor 601.

In the illustrative embodiment, the IC capacitor structure 100A includes an electrode 102 comprising a cylindrical column, a ferroelectric layer 104 around an exterior sidewall of the electrode 102. The capacitor structure 100A further includes an outer electrode 108 that is laterally adjacent to a first portion of an exterior of the ferroelectric layer 104, and an outer electrode 110 that is laterally adjacent to a second portion of the exterior of the ferroelectric layer 104. In one such embodiment, a vertical height of outer electrode 108 is substantially different from (e.g., greater than) a vertical height of outer electrode 110. In one embodiment, the second outer electrode 110 is above the first outer electrode 108, as shown. In the illustrative embodiment, the ferroelectric layer has a first ferroelectric layer portion adjacent to outer electrode 108 and a second ferroelectric layer portion adjacent to the outer electrode 110. Such ferroelectric layer portions can be programmed independently of each other. The IC capacitor structure 100A is adjacent to a region 630 above transistor 601. In some embodiments, transistor 601 includes peripheral IC structure elements, not shown.

The electrode 102 is further coupled with the transistor 601 through the conductive interconnect 118. As shown the conductive interconnect 118 is on and coupled with the drain contact 614 of the transistor 601. As shown, dielectric 124 is between the outer electrode 108 and dielectric 628. In the illustrative embodiment, dielectric 124 is also laterally adjacent to the electrode 102 and directly below and in contact with ferroelectric layer 104. The dielectric 124 may facilitate as an etch stop layer as well as a copper diffusion barrier layer.

In an embodiment, the underlying substrate 602 represents a surface used to manufacture ICs. Suitable substrate 602 includes a material such as single crystal silicon, polycrystalline silicon and silicon on insulator (SOI), as well as substrates formed of other semiconductor materials. In some embodiments, the substrate 602 may also include semiconductor materials, metals, dielectrics, dopants, and other materials commonly found in semiconductor substrates.

In an embodiment, the transistor 601 associated with substrate 602 are metal-oxide-semiconductor field-effect transistors (MOSFET or simply MOS transistors), fabricated on the substrate 602. In some embodiments, the transistor 601 is an access transistor 601. In various implementations of the disclosure, the transistor 601 may be planar transistors, nonplanar transistors, or a combination of both. Nonplanar transistors include FinFET transistors such as double-gate transistors and tri-gate transistors.

In some embodiments, gate 603 includes at least two layers, a gate dielectric layer 603A and a gate electrode 603B. The gate dielectric layer 603A may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer 603A to improve its quality when a high-k material is used.

The gate electrode 603B of the access transistor 601 of substrate 602 is formed on the gate dielectric layer 603A and may consist of at least one P-type work function metal or N-type work function metal, depending on whether the transistor is to be a PMOS or an NMOS transistor. In some implementations, the gate electrode 603B may consist of a stack of two or more metal layers, where one or more metal layers are work function metal layers and at least one metal layer is a conductive fill layer.

For a PMOS transistor, metals that may be used for the gate electrode 603B include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.6 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.6 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode 603B may simply be a planar layer that is substantially parallel to the top surface of the substrate and does not include sidewall portions substantially perpendicular to the top surface of the substrate. In further implementations of the disclosure, the gate electrode may comprise a combination of U-shaped structures and planar, non-U-shaped structures. For example, the gate electrode 603B may comprise one or more U-shaped metal layers formed atop one or more planar, non-U-shaped layers.

The sidewall spacers 610 may be formed from a material such as silicon nitride, silicon oxide, silicon carbide, silicon nitride doped with carbon, and silicon oxynitride. Processes for forming sidewall spacers include deposition and etching process operations. In an alternate implementation, a plurality of spacer pairs may be used, for instance, two pairs, three pairs, or four pairs of sidewall spacers may be formed on opposing sides of the gate stack. As shown, the source region 604 and drain region 606 are formed within the substrate adjacent to the gate stack of each MOS transistor. The source region 604 and drain region 606 are generally formed using either an implantation/diffusion process or an etching/deposition process. In the former process, dopants such as boron, aluminum, antimony, phosphorous, or arsenic may be ion-implanted into the substrate to form the source region 604 and drain region 606. An annealing process that activates the dopants and causes them to diffuse further into the substrate typically follows the ion implantation process. In the latter process, the substrate 602 may first be etched to form recesses at the locations of the source and drain regions. An epitaxial deposition process may then be carried out to fill the recesses with material that is used to fabricate the source region 604 and drain region 606. In some implementations, the source region 604 and drain region 606 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 604 and drain region 606 may be formed using one or more alternate semiconductor materials such as germanium or a group III-V material or alloy. And in further embodiments, one or more layers of metal and/or metal alloys may be used to form the source region 604 and drain region 606.

In an embodiment, the source contact 612, the drain contact 614 and gate contact 616 each include liner layer and a fill metal on the liner layer. In an embodiment, the liner layer includes one or more of Ti, Ru or Al and the fill metal includes W or Ni.

In an embodiment, the source interconnect 626, gate interconnect 624, each include a liner layer and a fill metal on the liner layer, as shown. In an embodiment, the liner layer includes one or more of Ti, Ta, Ru or Al. The fill metal may include a material such as W or Cu.

The isolation 608 and dielectric 618 and 628 may each include any material that has sufficient dielectric strength to provide electrical isolation. Materials may include silicon and one or more of oxygen, nitrogen or carbon such as silicon dioxide, silicon nitride, silicon oxynitride, carbon doped nitride or carbon doped oxide.

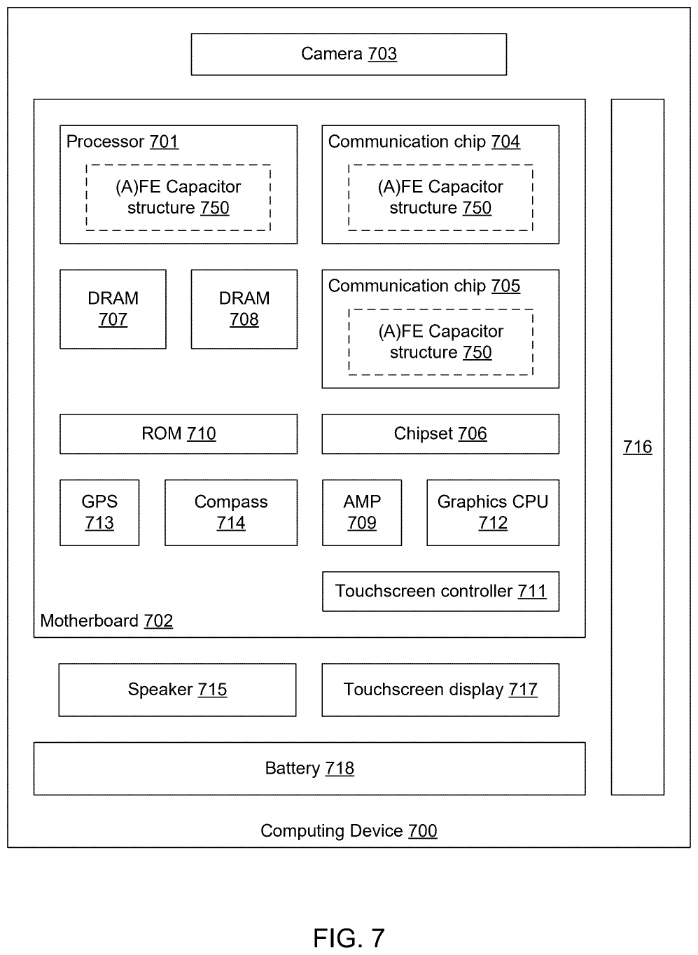

FIG. 7 illustrates a computing device 700 in accordance with some embodiments. As shown, computing device 700 houses a motherboard 702. Motherboard 702 may include a number of components, including but not limited to a processor 701 and at least one communications chip 704 or 705. Processor 701 is physically and electrically coupled to the motherboard 702. In some implementations, communications chip 705 is also physically and electrically coupled to motherboard 702. In further implementations, communications chip 705 is part of processor 701.

Depending on its applications, computing device 700 may include other components that may or may not be physically and electrically coupled to motherboard 702. These other components include, but are not limited to, volatile memory (e.g., DRAM), non-volatile memory (e.g., ROM), flash memory, a graphics processor, a digital signal processor, a crypto processor, a chipset 706, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communications chip 705 enables wireless communications for the transfer of data to and from computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communications chip 705 may implement any of a number of wireless standards or protocols, including but not limited to Wi-Fi (IEEE 801.11 family), WiMAX (IEEE 801.11 family), long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 700 may include a plurality of communications chips 704 and 705. For instance, a first communications chip 705 may be dedicated to shorter range wireless communications such as Wi-Fi and Bluetooth and a second communications chip 704 may be dedicated to longer range wireless communications such as GPS, EDGE, GPRS, CDMA, WiMAX, LTE, Ev-DO, and others.

Processor 701 of the computing device 700 includes an IC die packaged within processor 701. In some embodiments, the IC die of processor 701 includes one or more interconnect structures, non-volatile memory devices, and transistors coupled with one or more (A)FE capacitor structures 750 such as one of IC capacitor structures 100A, 100B, 400. Referring again to FIG. 7, the term “processor” may refer to any device or portion of a device that processes electronic data from registers and/or memory to transform that electronic data into other electronic data that may be stored in registers and/or memory.

Communications chip 705 also includes an IC die packaged within communication chip 705. In another embodiment, the IC die of communications chips 704, 705 includes one or more interconnect structures, non-volatile memory devices, one or more (A)FE capacitor structures 750 (such as one of IC capacitor structures 100A, 100B, 400), and one or more transistors coupled with said one or more (A)FE capacitor structures 750. Depending on its applications, computing device 700 may include other components that may or may not be physically and electrically coupled to motherboard 702. These other components may include, but are not limited to, volatile memory (e.g., DRAM, eDRAM) 707, DRAM 708, non-volatile memory (e.g., ROM) 710, a graphics CPU 712, flash memory, global positioning system (GPS) device 713, compass 714, a chipset 706, an antenna 716, a power amplifier 709, a touchscreen controller 711, a touchscreen display 717, a speaker 715, a camera 703, and a battery 718, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like. In further embodiments, any component housed within computing device 700 and discussed above may contain a stand-alone IC memory die that includes one or more arrays of nonvolatile memory devices.

In various implementations, the computing device 700 may be a laptop, a netbook, a notebook, an Ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

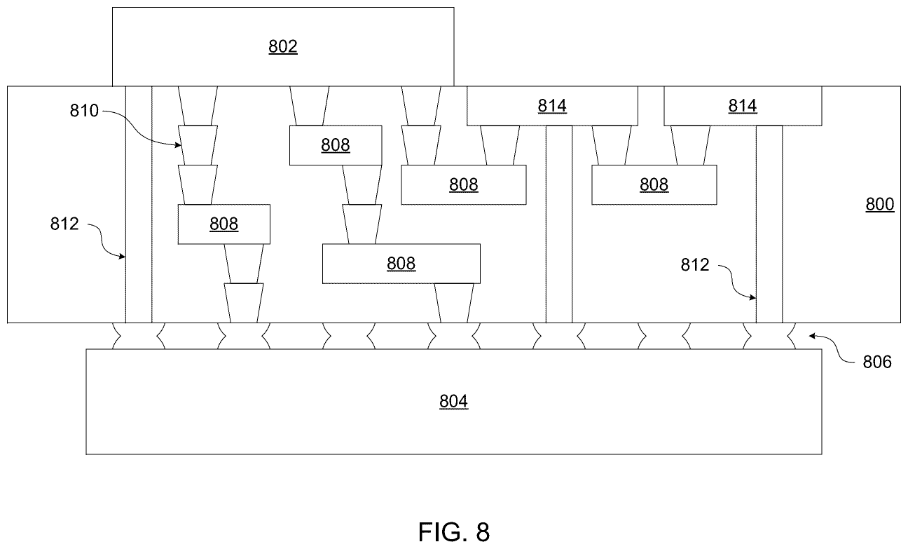

FIG. 8 illustrates an integrated circuit (IC) structure 800 that includes one or more embodiments. The integrated circuit (IC) structure 800 is an intervening substrate used to bridge a first substrate 802 to a second substrate 804. The first substrate 802 may be, for instance, an integrated circuit die. The second substrate 804 may be, for instance, a memory module, a computer mother, or another integrated circuit die. Generally, the purpose of an integrated circuit (IC) structure 800 is to spread a connection to a wider pitch or to reroute a connection to a different connection. For example, an integrated circuit (IC) structure 800 may couple an integrated circuit die to a ball grid array (BGA) 806 that can subsequently be coupled to the second substrate 804. In some embodiments, the first substrate 802 and the second substrate 804 are attached to opposing sides of the integrated circuit (IC) structure 800. In other embodiments, the first substrate 802 and the second substrate 804 are attached to the same side of the integrated circuit (IC) structure 800. And in further embodiments, three or more substrates are interconnected by way of the integrated circuit (IC) structure 800.

The integrated circuit (IC) structure 800 may be formed of an epoxy resin, a fiberglass-reinforced epoxy resin, a ceramic material, or a polymer material such as polyimide. In further implementations, the integrated circuit (IC) structure may be formed of alternate rigid or flexible materials that may include the same materials described above for use in a semiconductor substrate, such as silicon, germanium, and other group III-V and group IV materials.

The integrated circuit (IC) structure may include metal interconnects 808 and vias 810, including but not limited to through-silicon vias (TSVs) 812. The integrated circuit (IC) structure 800 may further include embedded devices 814, including both passive and active devices. Such embedded devices 814 include capacitors, decoupling capacitors such as one or more of capacitors 100A, 100B, 400, as described above, resistors, inductors, fuses, diodes, transformers, device structure including transistors, such as transistor 601 coupled with at least capacitor 100A as described in FIG. 6. Referring again to FIG. 8, the integrated circuit (IC) structure 800 may further include embedded devices 814 such as one or more resistive random-access devices, sensors, and electrostatic discharge (ESD) devices. More complex devices such as radiofrequency (RF) devices, power amplifiers, power management devices, antennas, arrays, sensors, and MEMS devices may also be formed on the integrated circuit (IC) structure 800.

Thus, one or more embodiments relate to IC capacitor devices such as one of IC capacitor structures 100A, 100B, 400 as described above. The capacitors 100A, 100B, 400 may be used in various integrated circuit applications.

In one or more first embodiments, an integrated circuit (IC) comprises a material layer stack comprising a first metallization layer and a second metallization layer, wherein a first vertical thickness of the first metallization layer is substantially greater than a second vertical thickness of the second metallization layer, a recess structure which extends vertically through each of the first metallization layer and the second metallization layer, a layer of an (anti)ferroelectric material in the recess structure, and an electrode structure in the recess structure, wherein the layer of the (anti)ferroelectric material extends around the electrode structure in a horizontal plane.

In one or more second embodiments, further to the first embodiment, the electrode structure comprises a first portion which extends through the first metallization layer, and a second portion which extends through the second metallization layer, and a first horizontal width of the first portion is substantially less than a second horizontal width of the second portion.

In one or more third embodiments, further to the second embodiment, in a vertical cross-section, the electrode structure tapers in horizontal width along a line of direction from the second metallization layer toward the first metallization layer.

In one or more fourth embodiments, further to the second embodiment, in a vertical cross-section, the electrode structure forms a substantial step-wise change in horizontal width.

In one or more fifth embodiments, further to the first embodiment or the second embodiment, the material layer stack further comprises a first dielectric layer and a second dielectric layer on opposite respective sides of the second metallization layer, wherein the first dielectric layer is between the first metallization layer and the second metallization layer, the second metallization layer forms an undercut structure with the first dielectric layer and the second dielectric layer.

In one or more sixth embodiments, further to the first embodiment or the second embodiment, the IC further comprises a first interconnect and a second interconnect which extend to the first metallization layer and the second metallization layer, respectively, and a third interconnect which extends to the electrode structure at a side of the material layer stack.

In one or more seventh embodiments, further to the first embodiment or the second embodiment, the electrode structure comprises a first portion which extends through the first metallization layer, and a second portion which extends through the second metallization layer, the layer of the (anti)ferroelectric material comprises a third portion which extends through the first metallization layer, and a fourth portion which extends through the second metallization layer, a first capacitor is formed with the first metallization layer, the first portion and the third portion, and a second capacitor is formed with the second metallization layer, the second portion and the fourth portion.

In one or more eighth embodiments, further to the seventh embodiment, the second metallization layer is between the first metallization layer and a third metallization layer of the material layer stack, the second vertical thickness of the second metallization layer is substantially greater than a third vertical thickness of the third metallization layer, the electrode structure further comprises a fifth portion which extends through the third metallization layer, the layer of the (anti)ferroelectric material comprises a sixth portion which extends through the third metallization layer, and a third capacitor is formed with the third metallization layer, the fifth portion and the sixth portion.

In one or more ninth embodiments, further to the first embodiment or the second embodiment, a memory cell comprises a transistor and n capacitors of the IC, wherein n is a positive integer.

In one or more tenth embodiments, a method comprises providing a material layer stack comprising a first metallization layer and a second metallization layer, wherein a first vertical thickness of the first metallization layer is substantially greater than a second vertical thickness of the second metallization layer, forming a recess structure which extends vertically through each of the first metallization layer and the second metallization layer, forming in the recess structure a layer of an (anti)ferroelectric material, and forming an electrode structure in the recess structure, wherein the layer of the (anti)ferroelectric material extends around the electrode structure in a horizontal plane.

In one or more eleventh embodiments, further to the tenth embodiment, the method further comprises forming a first interconnect and a second interconnect which extend to the first metallization layer and the second metallization layer, respectively, and forming a third interconnect which extends to the electrode structure at a side of the material layer stack.

In one or more twelfth embodiments, further to the tenth embodiment or the eleventh embodiment, forming the electrode structure comprises forming a first electrode portion which extends through the first metallization layer, and a second electrode portion which extends through the second metallization layer, a first horizontal width of the first electrode portion is substantially less than a second horizontal width of the second electrode portion.

In one or more thirteenth embodiments, further to the twelfth embodiment, in a vertical cross-section, the electrode structure tapers in horizontal width along a line of direction from the second metallization layer toward the first metallization layer.

In one or more fourteenth embodiments, further to the twelfth embodiment, in a vertical cross-section, the electrode structure forms a substantial step-wise change in horizontal width.

In one or more fifteenth embodiments, further to the tenth embodiment or the eleventh embodiment, the material layer stack further comprises a first dielectric layer and a second dielectric layer on opposite respective sides of the second metallization layer, wherein the first dielectric layer is between the first metallization layer and the second metallization layer, the second metallization layer forms an undercut structure with the first dielectric layer and the second dielectric layer.

In one or more sixteenth embodiments, further to the tenth embodiment or the eleventh embodiment, forming the electrode structure comprises forming a first electrode portion which extends through the first metallization layer, and a second electrode portion which extends through the second metallization layer, forming the layer of the (anti)ferroelectric material comprises forming a first ferroelectric portion which extends through the first metallization layer, and a second ferroelectric portion which extends through the second metallization layer, a first capacitor is formed with the first metallization layer, the first electrode portion and the first ferroelectric portion, and a second capacitor is formed with the second metallization layer, the second electrode portion and the second ferroelectric portion.

In one or more seventeenth embodiments, further to the sixteenth embodiment, the second metallization layer is between the first metallization layer and a third metallization layer of the material layer stack, the second vertical thickness of the second metallization layer is substantially greater than a third vertical thickness of the third metallization layer, the electrode structure further comprises a third electrode portion which extends through the third metallization layer, the layer of the (anti)ferroelectric material comprises a third ferroelectric portion which extends through the third metallization layer, and a third capacitor is formed with the third metallization layer, the third electrode portion and the third ferroelectric portion.

In one or more eighteenth embodiments, further to the tenth embodiment or the eleventh embodiment, a memory cell comprises a transistor and n capacitors of the IC capacitor structure, wherein n is a positive integer.

In one or more nineteenth embodiments, a system comprises an integrated circuit (IC) capacitor structure comprising a first outer electrode of a material layer stack, a second outer electrode of the material layer stack, a ferroelectric material layer which extends vertically through a recess formed in the material layer stack, wherein the recess layer extends through the first outer electrode and the second outer electrode, and wherein a first vertical thickness of the first outer electrode is substantially greater than a second vertical thickness of the outer electrode, and an inner electrode in the recess structure, wherein the ferroelectric material layer extends around the inner structure in a horizontal plane, and a transistor coupled to the IC capacitor structure, wherein a memory cell comprises the transistor and the IC capacitor structure.

In one or more twentieth embodiments, further to the nineteenth embodiment, the inner electrode comprises a first portion which extends through the first outer electrode, and a second portion which extends through the second outer electrode, and a first horizontal width of the first portion is substantially less than a second horizontal width of the second portion.

In one or more twenty-first embodiments, further to the twentieth embodiment, in a vertical cross-section, the inner electrode tapers in horizontal width along a line of direction from the second outer electrode toward the first outer electrode.

In one or more twenty-second embodiments, further to the twentieth embodiment, in a vertical cross-section, the inner electrode forms a substantial step-wise change in horizontal width.

In one or more twenty-third embodiments, further to the nineteenth embodiment or the twentieth embodiment, the material layer stack further comprises a first dielectric layer and a second dielectric layer on opposite respective sides of the second outer electrode, wherein the first dielectric layer is between the first outer electrode and the second outer electrode, the second outer electrode forms an undercut structure with the first dielectric layer and the second dielectric layer.

In one or more twenty-fourth embodiments, further to the nineteenth embodiment or the twentieth embodiment, the system further comprises a first interconnect and a second interconnect which extend to the first outer electrode and the second outer electrode, respectively, and a third interconnect which extends to the inner electrode at a side of the material layer stack.

In one or more twenty-fifth embodiments, further to the nineteenth embodiment or the twentieth embodiment, the inner electrode comprises a first portion which extends through the first outer electrode, and a second portion which extends through the second outer electrode, the ferroelectric material layer comprises a third portion which extends through the first outer electrode, and a fourth portion which extends through the second outer electrode, a first capacitor is formed with the first outer electrode, the first portion and the third portion, and a second capacitor is formed with the second outer electrode, the second portion and the fourth portion.

In one or more twenty-sixth embodiments, further to the twenty-fifth embodiment, the second outer electrode is between the first outer electrode and a third outer electrode of the material layer stack, the second vertical thickness of the second outer electrode is substantially greater than a third vertical thickness of the third outer electrode, the inner electrode further comprises a fifth portion which extends through the third outer electrode, the ferroelectric material layer comprises a sixth portion which extends through the third outer electrode, and a third capacitor is formed with the third outer electrode, the fifth portion and the sixth portion.

Techniques and architectures for providing an (anti)ferroelectric capacitor structure are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) comprising:
a material layer stack comprising a first metallization layer and a second metallization layer, wherein a first vertical thickness of the first metallization layer is substantially greater than a second vertical thickness of the second metallization layer;
a recess structure which extends vertically through each of the first metallization layer and the second metallization layer;
a layer of an (anti)ferroelectric material in the recess structure; and
an electrode structure in the recess structure, wherein the layer of the (anti)ferroelectric material extends around the electrode structure in a horizontal plane.

2. The IC of claim 1, wherein:
the electrode structure comprises:
a first portion which extends through the first metallization layer; and
a second portion which extends through the second metallization layer; and
a first horizontal width of the first portion is substantially less than a second horizontal width of the second portion.

3. The IC of claim 2, wherein, in a vertical cross-section, the electrode structure tapers in horizontal width along a line of direction from the second metallization layer toward the first metallization layer.

4. The IC of claim 2, wherein, in a vertical cross-section, the electrode structure forms a substantial step-wise change in horizontal width.

5. The IC of claim 1, wherein
the material layer stack further comprises a first dielectric layer and a second dielectric layer on opposite respective sides of the second metallization layer, wherein the first dielectric layer is between the first metallization layer and the second metallization layer;
the second metallization layer forms an undercut structure with the first dielectric layer and the second dielectric layer.

6. The IC of claim 1, further comprising:
a first interconnect and a second interconnect which extend to the first metallization layer and the second metallization layer, respectively; and
a third interconnect which extends to the electrode structure at a side of the material layer stack.

7. The IC of claim 1, wherein:
the electrode structure comprises:
a first portion which extends through the first metallization layer; and
a second portion which extends through the second metallization layer;
the layer of the (anti)ferroelectric material comprises:
a third portion which extends through the first metallization layer; and
a fourth portion which extends through the second metallization layer;
a first capacitor is formed with the first metallization layer, the first portion and the third portion; and
a second capacitor is formed with the second metallization layer, the second portion and the fourth portion.

8. The IC of claim 7, wherein
the second metallization layer is between the first metallization layer and a third metallization layer of the material layer stack;
the second vertical thickness of the second metallization layer is substantially greater than a third vertical thickness of the third metallization layer;
the electrode structure further comprises a fifth portion which extends through the third metallization layer;
the layer of the (anti)ferroelectric material comprises a sixth portion which extends through the third metallization layer; and
a third capacitor is formed with the third metallization layer, the fifth portion and the sixth portion.

9. The IC of claim 1, wherein a memory cell comprises a transistor and n capacitors of the IC, wherein n is a positive integer.

10. A method comprising:
providing a material layer stack comprising a first metallization layer and a second metallization layer, wherein a first vertical thickness of the first metallization layer is substantially greater than a second vertical thickness of the second metallization layer;
forming a recess structure which extends vertically through each of the first metallization layer and the second metallization layer;
forming in the recess structure a layer of an (anti)ferroelectric material; and
forming an electrode structure in the recess structure, wherein the layer of the (anti)ferroelectric material extends around the electrode structure in a horizontal plane.

11. The method of claim 10, wherein:
forming the electrode structure comprises forming:
a first electrode portion which extends through the first metallization layer; and
a second electrode portion which extends through the second metallization layer;
a first horizontal width of the first electrode portion is substantially less than a second horizontal width of the second electrode portion.

12. The method of claim 11, wherein, in a vertical cross-section, the electrode structure tapers in horizontal width along a line of direction from the second metallization layer toward the first metallization layer.

13. The method of claim 11, wherein, in a vertical cross-section, the electrode structure forms a substantial step-wise change in horizontal width.

14. The method of claim 10, wherein:
forming the electrode structure comprises forming:
a first electrode portion which extends through the first metallization layer; and
a second electrode portion which extends through the second metallization layer;
forming the layer of the (anti)ferroelectric material comprises forming:
a first ferroelectric portion which extends through the first metallization layer; and
a second ferroelectric portion which extends through the second metallization layer;
a first capacitor is formed with the first metallization layer, the first electrode portion and the first ferroelectric portion; and
a second capacitor is formed with the second metallization layer, the second electrode portion and the second ferroelectric portion.

15. A system comprising:
an integrated circuit (IC) capacitor structure comprising:
a first outer electrode of a material layer stack;
a second outer electrode of the material layer stack;
a ferroelectric material layer which extends vertically through a recess formed in the material layer stack, wherein the recess layer extends through the first outer electrode and the second outer electrode, and wherein a first vertical thickness of the first outer electrode is substantially greater than a second vertical thickness of the outer electrode; and
an inner electrode in the recess structure, wherein the ferroelectric material layer extends around the inner structure in a horizontal plane; and
a transistor coupled to the IC capacitor structure, wherein a memory cell comprises the transistor and the IC capacitor structure.

16. The system of claim 15, wherein:
the inner electrode comprises:
a first portion which extends through the first outer electrode; and
a second portion which extends through the second outer electrode; and
a first horizontal width of the first portion is substantially less than a second horizontal width of the second portion.

17. The system of claim 16, wherein, in a vertical cross-section, the inner electrode tapers in horizontal width along a line of direction from the second outer electrode toward the first outer electrode.

18. The system of claim 16, wherein, in a vertical cross-section, the inner electrode forms a substantial step-wise change in horizontal width.

19. The system of claim 15, further comprising:
a first interconnect and a second interconnect which extend to the first outer electrode and the second outer electrode, respectively; and
a third interconnect which extends to the inner electrode at a side of the material layer stack.

20. The system of claim 15, wherein:
the inner electrode comprises:
a first portion which extends through the first outer electrode; and
a second portion which extends through the second outer electrode;
the ferroelectric material layer comprises:
a third portion which extends through the first outer electrode; and
a fourth portion which extends through the second outer electrode;
a first capacitor is formed with the first outer electrode, the first portion and the third portion; and
a second capacitor is formed with the second outer electrode, the second portion and the fourth portion.
